(19) United States
(12) Patent Application Publication
(10) Pub. No.: US 2016/0064402 A1
(43) Pub. Date: Mar. 3, 2016

(54) METHOD FOR MANUFACTURING SEMICONDUCTOR DEVICE

(71) Applicant: Renesas Electronics Corporation, Tokyo (JP)

(72) Inventors: Kyoko Umeda, Tokyo (JP); Yoshiyuki Kawashima, Tokyo (JP); Hiraku Chakihara, Tokyo (JP)

(73) Assignee: RENESAS ELECTRONICS CORPORATION

(21) Appl. No.: 14/829,638

(22) Filed: Aug. 19, 2015

(30) Foreign Application Priority Data
Aug. 29, 2014 (JP) 2014-176569

(51) Int. Cl. H01L 27/115; H01L 21/3213; H01L 21/02; H01L 49/02; H01L 21/28

(52) U.S. Cl. CPC H01L 27/11568; H01L 27/11573; H01L 28/40; H01L 21/28282; H01L 21/0217; H01L 21/02164; H01L 21/022; H01L 21/32135

(57) ABSTRACT

In method for manufacturing a semiconductor device including a nonvolatile memory, a new method for manufacturing a capacitor element is provided. After working a control gate electrode, a gate insulation film including an electric charge accumulation section, and a memory gate electrode of a memory cell, in order to protect the memory cell, a p-type well of a MISFET is formed in a state the control gate electrode, the gate insulation film, and the memory gate electrode are covered by an insulation film. Also, this insulation film is used as a capacitor insulation film of a laminated type capacitor element.

### CROSS-REFERENCE TO RELATED APPLICATIONS

The disclosure of Japanese Patent Application No. 2014-176569 filed on Aug. 29, 2014 including the specification, drawings and abstract is incorporated herein by reference in its entirety.

### BACKGROUND

The present invention relates to a method for manufacturing a semiconductor device, and can be suitably utilized for a method for manufacturing a semiconductor device including a nonvolatile memory cell for example.

A semiconductor device has been widely used which includes a memory cell region where a memory cell and the like such as a nonvolatile memory for example is formed over a semiconductor substrate and a peripheral circuit region where a peripheral circuit including a MISFET (Metal Insulator Semiconductor Field Effect Transistor) and the like for example are formed over the semiconductor substrate.

For example, there is a case of forming a memory cell configured of a split gate type cell using a MONOS (Metal-Oxide-Nitride-Oxide-Semiconductor) film as a nonvolatile memory cell. This memory cell is configured of two MISFETs of a control transistor having a control gate electrode and a memory transistor having a memory gate electrode. Also, a gate insulation film of the memory transistor is configured of a laminated film including a silicon oxide film, a silicon nitride film and a silicon oxide film for example and called an ONO (Oxide Nitride Oxide) film.

Further, because a voltage higher than an electric supply voltage supplied from outside the semiconductor device is required for electrical writing and erasing operation of a nonvolatile memory, a booster circuit including a capacitor element is formed in the peripheral circuit region of the semiconductor device. Also, a by-pass capacitor (capacitor element) coupled between a power wiring (Vcc) and a grounding wiring (Gnd) of the semiconductor device is also built-in in the semiconductor device in order to stabilize the electric supply. For these capacitor elements, a PIP (Polysilicon Insulator Polysilicon) capacitor element is used which has an excellent matching property with the manufacturing process of the memory cell.

In Japanese Unexamined Patent Application Publication No. 2009-099640, a nonvolatile memory cell is disclosed which includes a control electrode (corresponding to the control gate electrode described above) 15, a memory gate electrode 26, and a laminated film (corresponding to the ONO film described above) arranged between the control electrode 15, a semiconductor substrate 10, and the memory gate electrode 26. Further, a capacitor element configured of a lower electrode 16, a capacitor insulation film 27 and an upper electrode 23 is also disclosed. Also, a manufacturing method is disclosed in which the control electrode 15 of the memory cell and the lower electrode 16 of the capacitor element are configured of a polysilicon film 14, the memory gate electrode 26 of the memory cell and the upper electrode 23 of the capacitor element are configured of a polysilicon film 20, and the capacitor insulation film 27 of the capacitor element is configured of the insulation film of the memory cell.

In Japanese Unexamined Patent Application Publication No. 2009-094204, a nonvolatile memory cell is disclosed which includes a selection gate electrode (corresponding to the control gate electrode described above) CG, a memory gate electrode MG, and an electric charge holding insulation film (corresponding to the ONO film described above) in which an insulation film 6b, an electric charge accumulation layer CSL, and an insulation film 6t are layered, and a high break down voltage system MIS including a gate insulation film 8a is disclosed for the peripheral circuit. Also, a laminated type capacitor element C1 is disclosed in which a first capacitor section and a second capacitor section are coupled in parallel, the first capacitor section is configured of a p-well PW, a first capacitor insulation film 8, and a lower electrode CGcb, and the second capacitor section is configured of a lower electrode CGcb, a second capacitor insulation film 9, and an upper electrode MGct. Further, the first capacitor insulation film 8 is configured of an insulation film of a same layer with the gate insulation film 8a of the high break down voltage system MIS, the lower electrode CGcb is configured of a conductor film of a same layer with the selection gate electrode CG, the upper electrode MGct is configured of a conductor film of a same layer with the memory gate electrode MG, and the second capacitor insulation film 9 is configured of an insulation film of a same layer with the electric charge holding insulation film that includes the insulation films 6b, 6t, and the electric charge accumulation layer CSL. Furthermore, a gate electrode 11a of the high break-down voltage system MIS is also configured of a conductor film of a same layer with the selection gate electrode CG.

### SUMMARY

A semiconductor device including a nonvolatile memory cell studied by the inventors of the present application includes a nonvolatile memory cell configured of a control gate electrode, an ONO film, and a memory gate electrode in a memory cell region, and includes a high break down voltage MISFET and a low break down voltage MISFET in a peripheral circuit region. The low break down voltage MISFET is configured in the order of a well region, a gate insulation film, a gate electrode, a source region, and a drain region, and the gate electrode of the low break down voltage MISFET is configured of a conductor layer of a same layer with a control gate electrode CG. More specifically, after forming the well region, the gate insulation film, and the conductor film for forming the gate electrode of the low break down voltage MISFET in the peripheral circuit region, the ONO film and the conductor film for the memory gate electrode are formed in the memory cell region.

Here, because the ONO film is formed in a comparatively high temperature, the impurity concentration profile of the well region of the low break down voltage MISFET fluctuates due to the thermal load in forming the ONO film, the threshold voltage and the like of the low break down voltage MISFET fluctuates, and thereafter a method for manufacturing a semiconductor device including a nonvolatile memory has been improved. Also, in the improved method for manufacturing a semiconductor device, study of a new method for manufacturing a capacitor element has become necessary. In other words, study of a new method for manufacturing a semiconductor device including a nonvolatile memory including a capacitor element has become necessary.

Other problems and new features will be clarified from the description of the present specification and the attached drawings.

According to an embodiment, in a method for manufacturing a semiconductor device, after working a control gate electrode, a layered film including an electric charge accumulation section, and a memory gate electrode in a memory cell region, a well of a MISFET of a peripheral circuit region is formed in a state the memory cell region is covered with a protection insulation film. Also, this protection insulation film is used as a capacitor insulation film in a lamination type capacitor element forming region of a peripheral circuit region.

According to an embodiment, in a method for manufacturing a semiconductor device including a nonvolatile memory, a new method for manufacturing a capacitor element is provided.

### BRIEF DESCRIPTION OF THE DRAWINGS

FIG. 1 is a drawing showing a layout configuration example of a semiconductor chip in the first embodiment.

FIG. 2 is an essential part cross-sectional view of a semiconductor device of the first embodiment.

FIG. 3A is an essential part plan view of a layered type capacitor element.

FIG. 3B is an explanatory drawing showing an example of a circuit configuration of the layered type capacitor element.

FIG. 4 is a process flow chart showing a part of a manufacturing step of the semiconductor device of the first embodiment.

FIG. 5 is a process flow chart showing a part of a manufacturing step of the semiconductor device of the first embodiment.

FIG. 6 is an essential part cross-sectional view during a manufacturing step of the semiconductor device of the first embodiment.

FIG. 7 is an essential part cross-sectional view during a manufacturing step of the semiconductor device of the first embodiment.

FIG. 8 is an essential part cross-sectional view during a manufacturing step of the semiconductor device of the first embodiment.

FIG. 9 is an essential part cross-sectional view during a manufacturing step of the semiconductor device of the first embodiment.

FIG. 10 is an essential part cross-sectional view during a manufacturing step of the semiconductor device of the first embodiment.

FIG. 11 is an essential part cross-sectional view during a manufacturing step of the semiconductor device of the first embodiment.

FIG. 12 is an essential part cross-sectional view during a manufacturing step of the semiconductor device of the first embodiment.

FIG. 13 is an essential part cross-sectional view during a manufacturing step of the semiconductor device of the first embodiment.

FIG. 14 is an essential part cross-sectional view during a manufacturing step of the semiconductor device of the first embodiment.

FIG. 15 is an essential part cross-sectional view during a manufacturing step of the semiconductor device of the first embodiment.

FIG. 16 is an essential part cross-sectional view during a manufacturing step of the semiconductor device of the first embodiment.

FIG. 17 is an essential part cross-sectional view during a manufacturing step of the semiconductor device of the first embodiment.

FIG. 18 is an essential part cross-sectional view during a manufacturing step of the semiconductor device of the first embodiment.

FIG. 19 is an essential part cross-sectional view during a manufacturing step of the semiconductor device of the first embodiment.

FIG. 20 is an essential part cross-sectional view during a manufacturing step of the semiconductor device of the first embodiment.

FIG. 21 is an essential part cross-sectional view of a semiconductor device of the second embodiment.

FIG. 22 is a process flow chart showing a part of a manufacturing step of the semiconductor device of the second embodiment.

FIG. 23 is a process flow chart showing a part of a manufacturing step of the semiconductor device of the second embodiment.

FIG. 24 is an essential part cross-sectional view during a manufacturing step of the semiconductor device of the second embodiment.

FIG. 25 is an essential part cross-sectional view during a manufacturing step of the semiconductor device of the second embodiment.

FIG. 26 is an essential part cross-sectional view during a manufacturing step of the semiconductor device of the second embodiment.

FIG. 27 is an essential part cross-sectional view during a manufacturing step of the semiconductor device of the second embodiment.

FIG. 28 is an essential part cross-sectional view during a manufacturing step of the semiconductor device of the second embodiment.

FIG. 29 is an essential part cross-sectional view of a semiconductor device of the third embodiment.

FIG. 30 is a process flow chart showing a part of a manufacturing step of the semiconductor device of the third embodiment.

FIG. 31 is a process flow chart showing a part of a manufacturing step of the semiconductor device of the third embodiment.

FIG. 32 is an essential part cross-sectional view during a manufacturing step of the semiconductor device of the third embodiment.

FIG. 33 is an essential part cross-sectional view during a manufacturing step of the semiconductor device of the third embodiment.

FIG. 34 is an essential part cross-sectional view during a manufacturing step of the semiconductor device of the third embodiment.

FIG. 35 is an essential part cross-sectional view during a manufacturing step of the semiconductor device of the third embodiment.

### DETAILED DESCRIPTION

In embodiments below, when it is required for the sake of convenience, although description will be made dividedly into plural sections or embodiments, they are not unrelated to each other, and one has a relationship of a modification, detail, supplementary explanation and the like of a part or entirety with the other with the exception of a case particularly stated.

Also, in embodiments below, when the quantity of elements and the like (including the number of pieces, numerical value, amount, range and the like) are mentioned, they are not limited to the specific quantity and may be equal to or more than and equal to or less than the specific quantity with the exception of a case particularly specified, a case apparently limited to a specific quantity in principle, and so on.

Further, in the embodiments below, it is needless to mention that the constituent elements thereof (including the elemental step and the like) are not necessarily indispensable with the exception of a case particularly specified, a case considered to be apparently indispensable in principle, and so on. In a similar manner, in the embodiments below, when the shape, the positional relation and the like of the formation elements and the like are mentioned, they are to contain one substantially approximate or similar to the shape and the like thereof and so on with the exception of a case particularly specified, a case apparently considered not to be the case in principle, and so on. This fact also applies to the numerical value and the range described above.

Below, representative embodiments will be explained in detail based on the drawings. Also, in all drawings for explaining the embodiments, a same reference sign will be given to a member having a same function, and repeated explanation thereon will be omitted. Further, in the embodiments below, explanation on a same or similar portions will not be repeated in principle except when it is particularly required.

Further, in the drawings used in the embodiments, there is also a case hatching is omitted in order to facilitate understanding of the drawing even in a cross-sectional view.

### First Embodiment

### Layout Configuration Example of Semiconductor Chip

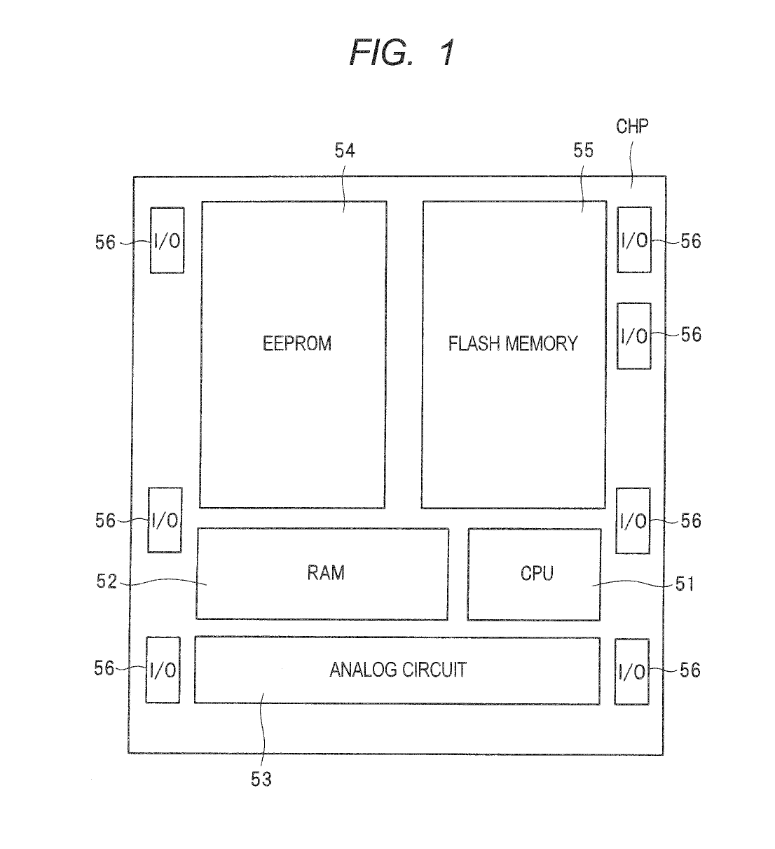

A semiconductor device including a nonvolatile memory in the present first embodiment will be explained referring to the drawings. First, a layout configuration of a semiconductor device (semiconductor chip) forming a system including a nonvolatile memory therein will be explained. FIG. 1 is a drawing showing a layout configuration example of a semiconductor chip CHP in the present first embodiment. In FIG. 1, the semiconductor chip CHP includes a CPU (Central Processing Unit) 51, a RAM (Random Access Memory) 52, an analog circuit 53, an EEPROM (Electrically Erasable Programmable Read Only Memory) 54, a flash memory 55, and I/O (Input/Output) circuits 56, and forms a semiconductor integrated circuit device.

The CPU (circuit) 51 is also called a central arithmetic processing unit, reads out a command from a storage device for interpretation, and performs various calculation and control based on it.

The RAM (circuit) 52 is a memory that can read out stored information and newly write stored information at random, and is also called a random writing and reading memory. With respect to the RAM as an IC memory, there are two kinds of a DRAM (Dynamic RAM) using a dynamic circuit, and a SRAM (Static RAM) using a static circuit. The DRAM is a random writing and reading memory that requires a memory holding operation, and the SRAM is random writing and reading memory that does not require the memory holding operation.

The analog circuit 53 is a circuit that handles a signal of the voltage and electric current temporally changing continuously which is an analog signal, and includes an amplifying circuit, conversion circuit, modulation circuit, oscillation circuit, power circuit and the like for example. Also, plural capacitor elements are included in the analog circuit 53.

The EEPROM 54 and the flash memory 55 are a kind of a nonvolatile memory in which both of the writing operation and erasing operation are electrically rewritable, and are also called an electrically erasable programmable read-only memory. The memory cell of these EEPROM 54 and flash memory 55 is configured of a MONOS type transistor and a MNOS (Metal Nitride Oxide Semiconductor) type transistor for example for storage (memory). For the writing operation and erasing operation of the EEPROM 54 and the flash memory 55, the Fowler-Nordheim tunneling effect for example is utilized. Further, the writing operation and erasing operation can be also performed using the hot electron and the hot hole. Because a voltage higher than the external power supply voltage is required for the writing operation and erasing operation of the EEPROM 54 and the flash memory 55, a booster circuit or the like is included in the EEPROM 54 and the flash memory 55, and plural capacitor elements are included in the booster circuit. The difference between the EEPROM 54 and the flash memory 55 is that the EEPROM 54 is a nonvolatile flash memory erasable in a bite unit for example, whereas the flash memory 55 is a nonvolatile memory erasable in a word line unit for example. In general, in the flash memory 55, a program and the like for performing various processes by the CPU are stored. On the other hand, in the EEPROM 54, various data with high rewriting frequency are stored.

The I/O circuit 56 is an input/output circuit, and is a circuit for outputting data from inside the semiconductor chip CHP to a device connected to the outside of the semiconductor chip CHP, and inputting data from a device coupled to the outside of the semiconductor chip CHP to inside the semiconductor chip CHP. Further, a by-pass capacitor (capacitor element) coupled between the power supply wiring (Vcc) and the grounding wiring (Gnd) of the semiconductor chip CHP is also arranged in the I/O circuit 56.

In the EEPROM 54 and the flash memory 55, the memory cells which are plural nonvolatile memories are disposed in a matrix. Also, the CPU 51, the RAM 52, the analog circuit 53, the I/O circuit 56, and the portion other than the memory cell of the EEPROM 54 and the flash memory 55 are formed using a high break down voltage MISFET and/or a low break down voltage MISFET. The high break down voltage MISFET and the low break down voltage MISFET are configured of an n-type MISFET and a p-type MISFET respectively.

### <Structure of Semiconductor Device>

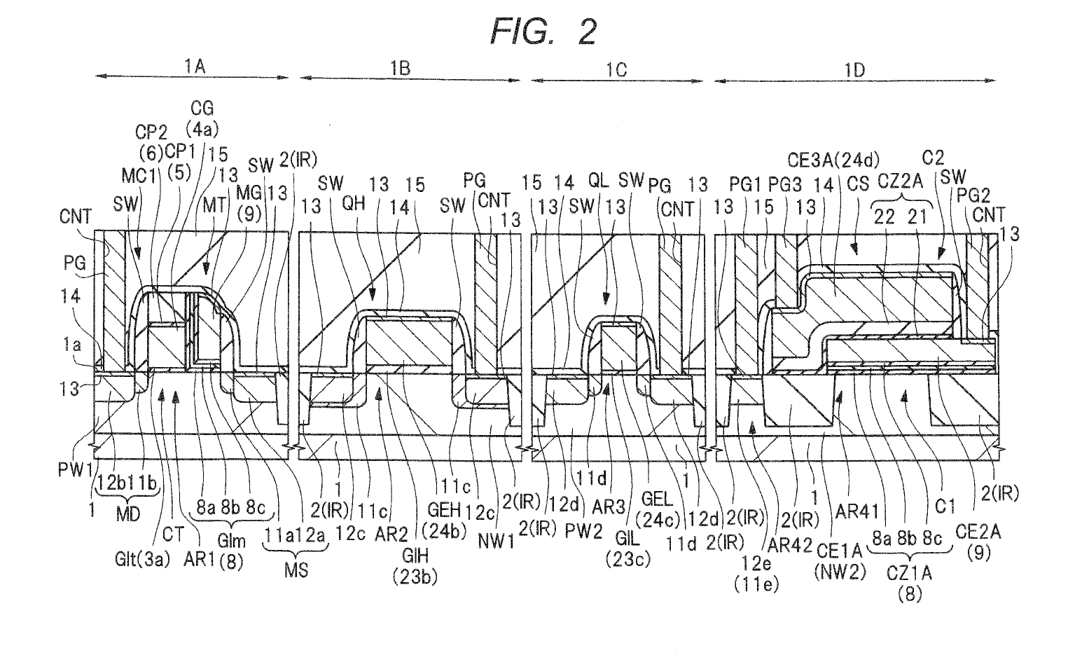

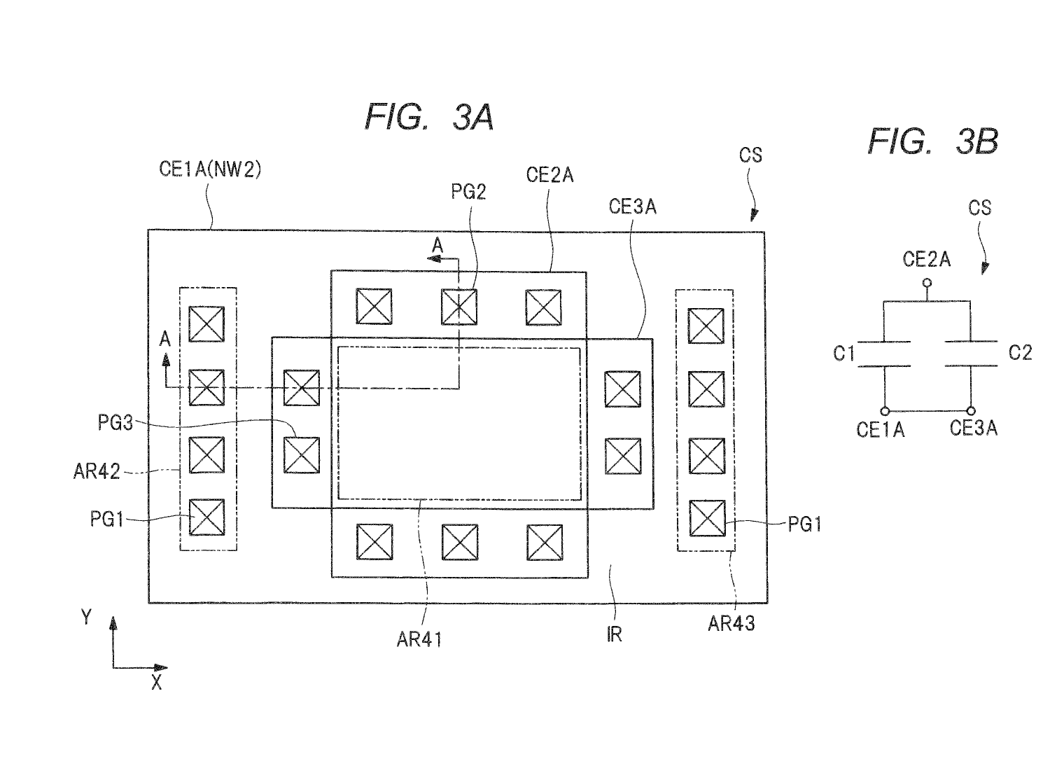

FIG. 2 is an essential part cross-sectional view of a semiconductor device of the first embodiment. FIG. 3A is an essential part plan view of a layered type capacitor element, and FIG. 3B is an explanatory drawing showing an example of a circuit configuration of the layered type capacitor element.

As shown in FIG. 2, the semiconductor device includes a semiconductor substrate 1. The semiconductor substrate 1 is a semiconductor wafer configured of a p-type mono-crystal silicon and the like having the specific resistance of approximately 1-10 Ωcm for example.

The semiconductor device includes a memory cell region 1A and peripheral circuit regions 1B, 1C and 1D as the regions of a part of a main surface 1a of the semiconductor substrate 1. A memory cell MC1 is formed in the memory cell region 1A, a MISFET QH that is a p-channel type high break down voltage MISFET is formed in the peripheral circuit region 1B, a MISFET QL that is an n-channel type low break down voltage MISFET is formed in the peripheral circuit region 1C, and a laminated type capacitor element CS is formed in the peripheral circuit region 1D. The memory cell region 1A corresponds to the EEPROM 54 or the flash memory 55 of FIG. 1.

First, the configuration of the memory cell MC1 formed in the memory cell region 1A will be explained specifically.

In the memory cell region 1A, the semiconductor device includes an active region AR1 and an element separation region IR. The element separation region IR is for separating elements formed in the active region AR1, and an element separation film 2 is formed in the element separation region IR. The active region AR1 is defined, or partitioned, by the element separation region IR and is electrically separated from other active regions by the element separation region IR, and a p-type well PW1 is formed in the active region AR1. The p-type well PW1 has the conductivity type of p-type.

As shown in FIG. 2, in the p-type well PW1 of the memory cell region 1A, the memory cell MC1 configured of a memory transistor MT and a control transistor CT is formed. In the memory cell region 1A, plural memory cells MC1 are formed in an array shape in practice, and a cross section of one memory cell MC1 out of them is illustrated in FIG. 2.

The memory cell MC1 is a memory cell of a split gate type. In other words, as shown in FIG. 2, the memory cell MC1 includes a control transistor CT that includes a control gate electrode CG and the memory transistor MT that is coupled to the control transistor CT and includes a memory gate electrode MG.

As shown in FIG. 2, the memory cell MC1 includes a semiconductor region MS of n-type, a semiconductor region MD of n-type, the control gate electrode CG, and the memory gate electrode MG. The semiconductor region MS of n-type and the semiconductor region MD of n-type have a conductivity type of n-type that is the conductivity type opposite of the conductivity type of p-type. Also, the memory cell MC1 includes a cap insulation film CP1 formed over the control gate electrode CG and a cap insulation film CP2 formed over the cap insulation film CP1. Further, the memory cell MC1 includes a gate insulation film GIt formed between the control gate electrode CG and a p-type well PW1 of the semiconductor substrate 1, and a gate insulation film GIm formed between the memory gate electrode MG and the p-type well PW1 of the semiconductor substrate 1 and between the memory gate electrode MG and the control gate electrode CG.

The control gate electrode CG and the memory gate electrode MG extend along the main surface 1a of the semiconductor substrate 1 and are arranged side by side in a state the gate insulation film GIm is interposed between the opposing side surfaces thereof which are the side walls. The extending direction of the control gate electrode CG and the memory gate electrode MG is the direction orthogonal to the paper surface of FIG. 2. The control gate electrode CG is formed over the p-type well PW1 of a portion positioned between the semiconductor region MD and the semiconductor region MS which means over the main surface 1a of the semiconductor substrate 1 through the gate insulation film GIt. Also, the memory gate electrode MG is formed over the p-type well PW1 of a portion positioned between the semiconductor region MD and the semiconductor region MS which means over the main surface 1a of the semiconductor substrate 1 through the gate insulation film GIm. Further, the memory gate electrode MG is arranged on the semiconductor region MS side, and the control gate electrode CG is arranged on the semiconductor region MD side. The control gate electrode CG and the memory gate electrode MG are gate electrodes forming the memory cell MC1 that is a nonvolatile memory.

Further, the cap insulation film CP1 and the cap insulation film CP2 formed over the control gate electrode CG also extend along the main surface 1a of the semiconductor substrate 1.

The control gate electrode CG and the memory gate electrode MG are adjacent to each other with the gate insulation film GIm being interposed in between, and the memory gate electrode MG is formed over the side surface, or over the side wall, of the control gate electrode CG into a side wall spacer shape through the gate insulation film GIm. Also, the gate insulation film GIm extends over both regions of the region between the memory gate electrode MG and the p-type well PW1 of the semiconductor substrate 1, and the region between the memory gate electrode MG and the control electrode CG.

The gate insulation film GIt is configured of an insulation film 3a. The insulation film 3a is configured of a silicon oxide film, a silicon nitride film or a silicon oxynitride film, or a high dielectric constant film having a specific dielectric constant higher than that of a silicon nitride film which is so-called High-k film. Also, when the High-k film or the high dielectric constant film is referred to in the present application, a film having the dielectric constant (specific dielectric constant) higher than that of a silicon nitride film is meant. As the insulation film 3a, a metal oxide film such as a hafnium oxide film, a zirconium oxide film, an aluminum oxide film, a tantalum oxide film, or a lanthanum oxide film can be used for example.

The gate insulation film GIm is configured of an insulation film 8. The insulation film 8 includes a silicon oxide film 8a, a silicon nitride film 8b as an electric charge accumulation section over the silicon oxide film 8a, and a silicon oxide film 8c over the silicon nitride film 8b, and is configured of a laminated layer called an ONO film. Also, the gate insulation film GIm between the memory gate electrode MG and the p-type well PW1 functions as a gate insulation film of the memory transistor MT as described above. On the other hand, the gate insulation film GIm between the memory gate electrode MG and the control gate electrode CG functions as an insulation film for insulating, or electrically separating from, the memory gate electrode MG and the control gate electrode CG each other.

Out of the insulation film 8, the silicon nitride film 8b is an insulation film for accumulating the electric charge, and functions as an electric charge accumulation section. More specifically, the silicon nitride film 8b is a trap type insulation film formed in the insulation film 8. Therefore, insulation film 8 can be deemed an insulation film having an electric charge accumulation section in the inside thereof.

The silicon oxide film 8c and the silicon oxide film 8a positioned on and beneath the silicon nitride film 8b can function as electric charge block layers for enclosing the electric charge. In other words, with a structure of embracing the silicon nitride film 8b by the silicon oxide film 8c and the silicon oxide film 8a, leakage of the electric charge accumulated in the silicon nitride film 8b is prevented.

The control gate electrode CG is configured of a conductor film 4a. The conductor film 4a is configured of silicon, and is configured of an n-type polysilicon film and the like that is a polycrystal silicone film to which n-type impurity for example is introduced. In other words, the control gate electrode CG is configured of a patterned conductor film 4a.

The memory gate electrode MG is configured of a conductor film 9. The conductor film 9 is configured of silicon, and is configured of an n-type polysilicon film and the like that is a polycrystal silicone film to which n-type impurity for example is introduced. The memory gate electrode MG is formed into a side wall spacer shape over a side wall positioned on one side of the control gate electrode CG that is adjacent to the memory gate electrode MG through the insulation film 8.

Over the control gate electrode CG, the cap insulation film CP2 is formed through the cap insulation film CP1. Therefore, the memory gate electrode MG is formed into a side wall spacer shape over a side wall positioned on one side of the cap insulation film CP2 formed over the control gate electrode CG that is adjacent to the memory gate electrode MG through the insulation film 8.

The cap insulation film CP1 is configured of an insulation film 5 containing silicon and oxygen. The insulation film 5 is configured of a silicon oxide film and the like for example. The cap insulation film CP2 is configured of an insulation film 6 containing silicon and nitrogen. The insulation film 6 is configured of a silicon nitride film and the like for example.

The cap insulation film CP2 is a protection film that protects the control gate electrode CG, is a hard mask film in patterning the conductor film 4 and forming the control gate electrode CG, or is a spacer film for adjusting the height of the memory gate electrode MG in etching back the conductor film 9 and forming the memory gate electrode MG. By forming the cap insulation film CP2 as a spacer film, the film thickness of the control gate electrode CG can be made smaller than the height of the memory gate electrode MG.

The semiconductor region MS is a semiconductor region that functions as one of the source region or the drain region, and the semiconductor region MD is a semiconductor region that functions as the other of the source region or the drain region. Here, the semiconductor region MS is a semiconductor region that functions as the source region for example, and the semiconductor region MD is a semiconductor region that functions as the drain region for example. Each of the semiconductor region MS and the semiconductor region MD is configured of a semiconductor region to which n-type impurity has been introduced, and has an LDD (Lightly Doped Drain) structure respectively.

The semiconductor region MS for the source includes an n⁻ type semiconductor region 11a, and an n⁺ type semiconductor region 12a having the impurity concentration higher than that of the n⁻ type semiconductor region 11a. Also, the semiconductor region MD for the drain includes an n⁻ type semiconductor region 11b and an n⁺ type semiconductor region 12b that has the impurity concentration higher than that of the n⁻ type semiconductor region 11b. The n⁺ type semiconductor region 12a has a deeper junction depth and a higher impurity concentration compared to the n⁻ type semiconductor region 11a, and the n⁺ type semiconductor region 12b has a deeper junction depth and a higher impurity concentration compared to the n⁻ type semiconductor region 11b.

Over a side wall on the drain region side of the control gate electrode CG and over a side wall on the source region side of the memory gate electrode MG, a side wall spacer SW configured of an insulation film such as a silicon oxide film, a silicon nitride film, or a layered film thereof is formed.

The n⁻ type semiconductor region 11a is formed in a self-aligned manner with respect to the side surface of the memory gate electrode MG, and the n⁺ type semiconductor region 12a is formed in a self-aligned manner with respect to the side surface of the side wall spacer SW. Therefore, the n⁻ type semiconductor region 11a of a low concentration is formed below the side wall spacer SW over the side wall of the memory gate electrode MG, and the n⁺ type semiconductor region 12a of a high concentration is formed outside the n⁻ type semiconductor region 11a of a low concentration.

The n⁻ type semiconductor region 11b is formed in a self-aligned manner with respect to the side surface of the control gate electrode CG, and the n⁺ type semiconductor region 12b is formed in a self-aligned manner with respect to the side surface of the side wall spacer SW. Therefore, the n⁻ type semiconductor region 11b of a low concentration is formed below the side wall spacer SW over the side wall of the control gate electrode CG, and the n⁺ type semiconductor region 12b of a high concentration is formed outside the n⁻ type semiconductor region 11b of a low concentration. Therefore, the n⁻ type semiconductor region 11b of a low concentration is formed so as to be adjacent to the p-type well PW1 as a channel region of the control transistor CT.

The channel region of the memory transistor MT is formed below the gate insulation film GIm below the memory gate electrode MG, and the channel region of the control transistor CT is formed below the gate insulation film GIt below the control gate electrode CG.

Over the n⁺ type semiconductor region 12a or over the n⁺ type semiconductor region 12b, that is over the upper surface of the n⁺ type semiconductor region 12a or the n⁺ type semiconductor region 12b, a metal silicide layer 13 is formed by the salicide (Self Aligned Silicide) technology and the like. The metal silicide layer 13 is configured of a cobalt silicide layer, a nickel silicide layer, or a platinum-added nickel silicide layer, and the like for example. By the metal silicide layer 13, the diffusion resistance and the contact resistance can be lowered. Also, the metal silicide layer 13 may be formed over the memory gate electrode MG.

Next, the configuration of the high break down voltage MISFET QH of p-channel type formed in the peripheral circuit region 1B will be explained specifically.

In the peripheral circuit region 1B, the semiconductor device includes an active region AR2 and the element separation region IR. The structure and the function of the element separation region IR are as described above. The active region AR2 is defined, or partitioned, by the element separation region IR and is electrically separated from other active regions by the element separation region IR, and an n-type well NW1 is formed in the active region AR2. In other words, the active region AR2 is a region where the n-type well NW1 is formed. The n-type well NW1 has the conductivity type of n-type.

As shown in FIG. 2, the high break down voltage MISFET QH includes a semiconductor region configured of a p⁻ type semiconductor region 11c and a p⁺ type semiconductor region 12c, a gate insulation film GIH formed over the n-type well NW1, and a gate electrode GEH formed over the gate insulation film GIH. The p⁻ type semiconductor region 11c and the p⁺ type semiconductor region 12c are formed in the upper layer section of the n-type well NW1 of the semiconductor substrate 1. The p⁻ type semiconductor region 11c and the p⁺ type semiconductor region 12c have the conductivity type of p-type which is the conductivity type opposite to the conductivity type of n-type.

The gate insulation film GIH functions as a gate insulation film of the MISFET QH. The gate insulation film GIH is configured of an insulation film 23b. The insulation film 23b is configured of a silicon oxide film, a silicon nitride film or a silicon oxynitride film, or a high dielectric constant film having a specific dielectric constant higher than that of the silicon nitride film which is so-called High-k film. As the insulation film 23b configured of the High-k film, a metal oxide film such as a hafnium oxide film, a zirconium oxide film, an aluminum oxide film, a tantalum oxide film, or a lanthanum oxide film can be used for example.

The gate electrode GEH is configured of a conductor film 24b. The conductor film 24b is configured of silicon, and is configured of a p-type polysilicon film and the like that is a polycrystal silicone film to which p-type impurity for example has been introduced. In other words, the gate electrode GEH is configured of the patterned conductor film 24b. The conductor film 24b is configured of a conductor film different from the conductor film 4a included in the control gate electrode CG.

A semiconductor region configured of the p⁻ type semiconductor region 11c and the p⁺ type semiconductor region 12c is a semiconductor region for the source and for the drain (the source region and the drain region) to which p-type impurity has been introduced, and has the DDD (Double Diffused Drain) structure. More specifically, the p⁺ type semiconductor region 12c has a deeper junction depth and a higher impurity concentration compared to the p⁻ type semiconductor region 11c.

Over a side wall of the gate electrode GEH, the side wall spacer SW configured of an insulation film such as a silicon oxide film, a silicon nitride film, or a layered film thereof is formed.

Over the p⁺ type semiconductor region 12c, that is over the upper surface of the p⁺ type semiconductor region 12c, the metal silicide layer 13 is formed by the salicide technology and the like similarly to over the n⁺ type semiconductor region 12a or over the n⁺ type semiconductor region 12b in the memory cell MC1. Further, the metal silicide layer 13 is formed over the gate electrode GEH also.

Next, the configuration of the low break down voltage MISFET QL of an n-channel type formed in the peripheral circuit region 1C will be explained specifically.

In the peripheral circuit region 1C, the semiconductor device includes an active region AR3 and the element separation region IR. The structure and the function of the element separation region IR are as described above. The active region AR3 is defined, or partitioned, by the element separation region IR and is electrically separated from other active regions by the element separation region IR, and a p-type well PW2 is formed in the active region AR3. In other words, the active region AR3 is a region where the p-type well PW2 is formed. The p-type well PW2 has the conductivity type of p-type.

As shown in FIG. 2, the low break down voltage MISFET QL includes a semiconductor region configured of an n⁻ type semiconductor region 11d and an n⁺ type semiconductor region 12d, a gate insulation film GIL formed over the p-type well PW2, and a gate electrode GEL formed over the gate insulation film GIL. The n⁻ type semiconductor region 11d and the n⁺ type semiconductor region 12d are formed in the upper layer section of the p-type well PW2 of the semiconductor substrate 1. The n⁻ type semiconductor region 11d and the n⁺ type semiconductor region 12d have the conductivity type of n-type which is the conductivity type opposite to the conductivity type of p-type.

The gate insulation film GIL functions as the gate insulation film of the MISFET QL. The gate insulation film GIL is configured of an insulation film 23c.

The gate electrode GEL is configured of a conductor film 24c. As the conductor film 24c, a conductor film formed in the same layer of the conductor film 24b included in the gate electrode GEH of the MISFET QH can be used.

A semiconductor region configured of the n⁻ type semiconductor region 11d and the n⁺ type semiconductor region 12d is a semiconductor region for the source and for the drain (the source region and the drain region) to which n-type impurity has been introduced, and has the LDD structure similarly to the semiconductor regions MS and MD of the memory cell MC1. More specifically, the n⁺ type semiconductor region 12d has a deeper junction depth and a higher impurity concentration compared to the n⁻ type semiconductor region 11d.

Over a side wall of the gate electrode GEL, the side wall spacer SW configured of an insulation film such as a silicon oxide film, a silicon nitride film, or a laminated film thereof is formed.

Over the n⁺ type semiconductor region 12d, or over the upper surface of the n⁺ type semiconductor region 12d, the metal silicide layer 13 is formed by the salicide technology and the like similarly to over the n⁺ type semiconductor region 12a or over the n⁺ type semiconductor region 12b in the memory cell MC1. Further, the metal silicide layer 13 is formed over the gate electrode GEL also.

Further, the low break down voltage MISFET QL may include a halo region although illustration thereof will be omitted. The conductivity type of the halo region is the conductivity type opposite to that of the n⁻ type semiconductor region 11d and is the conductivity type same to that of the p-type well PW2. The halo region is formed to suppress the short channel characteristics (punch through). The halo region is formed so as to encompass the n⁻ type semiconductor region 11d, and the concentration of the p-type impurity in the halo region is higher than the concentration of the p-type impurity in the p-type well PW2.

It is preferable that the gate length of the high break down voltage MISFET QH is longer than the gate length of the low break down voltage MISFET QL. Also, the drive voltage of the high break down voltage MISFET QH is higher than the drive voltage of the low break down voltage MISFET QL, and the break down voltage of the high break down voltage MISFET QH is higher than the break down voltage of the low break down voltage MISFET QL.

It is preferable that a film thickness TIH of the gate insulation film GIH is thicker than a film thickness TIL of the gate insulation film GIL. Thus, the drive voltage of the high break down voltage MISFET QH can be made higher than the drive voltage of the low break down voltage MISFET QL.

Next, the configuration of the laminated type capacitor element CS formed in the peripheral circuit region 1D will be explained specifically.

In the peripheral circuit region 1D, the semiconductor device includes active regions AR41, AR42, and the element separation region IR. The structure and the function of the element separation region IR are as described above. In the lower part of the active regions AR41, AR42, and the element separation region IR, an n-type well NW2 is continuously formed. The active region AR42 is a region for supplying desired potential to the n-type well NW2, and an n⁺ type semiconductor region 12e and an n⁻ type semiconductor region 11e are arranged in the active region AR42. The n-type well NW2 forms a first capacitor electrode CE1A. The n-type well NW2 forming the first capacitor electrode CE1A is formed by a step same to that of the n-type well NW1 where the p-type MISFET QH is formed.

Over the active region AR41, a second capacitor electrode CE2A is formed through a first capacitor insulation film CZ1A. In plan view, the second capacitor electrode CE2A fully covers the active region AR41, and extends to the element separation region IR adjacent to the active region AR41. The first capacitor insulation film CZ1A includes the silicon oxide film 8a, the silicon nitride film 8b over the silicon oxide film 8a, and the silicon oxide film 8c over the silicon nitride film 8b, and the silicon oxide film 8a, the silicon nitride film 8b, and the silicon oxide film 8c are respectively configured of same layers of the silicon oxide film 8a, the silicon nitride film 8b, and the silicon oxide film 8c in the memory cell region 1A. The second capacitor electrode CE2A is configured of the conductor film 9, and is configured of a conductor film of the same layer of the memory gate electrode MG. Also, the second capacitor electrode CE2A and the first capacitor insulation film CZ1A have a same shape in plan view.

In other words, a first capacitor C1 configured of the first capacitor electrode CE1A, the first capacitor insulation film CZ1A, and the second capacitor electrode CE2A is formed in the active region AR41.

So as to cover the upper surface and the side surface of the second capacitor electrode CE2A, a third capacitor electrode CE3A is formed through a second capacitor insulation film CZ2A. The third capacitor electrode CE3A includes a portion overlapping with the second capacitor electrode CE2A in plan view and a portion spreading out from the second capacitor electrode CE2A and extending to the element separation region IR in plan view. The third capacitor electrode CE3A is configured of a conductor film 24d. As the conductor film 24d, a conductor film formed in the same layer of the conductor film 24b included in the gate electrode GEH of the MISFET QH or of the conductor film 24c included in the gate electrode GEL of the MISFET QL can be used. Also, the second capacitor insulation film CZ2A is configured of a laminated film of an insulation film 21 and an insulation film 22 formed over the insulation film 21. The insulation film 21 is configured of a silicon oxide film, and the insulation film 22 is configured of a silicon nitride film. The laminated film of the insulation film 21 and the insulation film 22 is formed so as to cover the upper surface and the side surface of the second capacitor electrode CE2A, and extends to the element separation region IR. The third capacitor electrode CE3A and the second capacitor insulation film CZ2A have a same shape in plan view. The side wall spacer SW is formed in the side wall of the third capacitor electrode CE3A and the second capacitor insulation film CZ2A.

In other words, a second capacitor C2 configured of the second capacitor electrode CE2A, the second capacitor insulation film CZ2A, and the third capacitor electrode CE3A is formed in a region where the second capacitor electrode CE2A and the third capacitor electrode CE3A overlap. Because the third capacitor electrode CE3A also fully covers the active region AR41 in plan view, the laminated type capacitor element CS in which the first capacitor C1 and the second capacitor C2 are laminated is formed in the active region AR41.

The metal silicide layers 13 are formed over the upper surface of the second capacitor electrode CE2A exposed from the third capacitor electrode CE3A and the side wall spacer SW and over the upper surface of the third capacitor electrode CE3A over the n⁺ type semiconductor region 12e.

Next, the configuration of the laminated type capacitor element CS will be explained using FIG. 3A and FIG. 3B.

As shown in FIG. 3A, the laminated type capacitor element CS has a structure of laminating the first capacitor electrode CE1A of a rectangle having the longer side in the lateral direction, the second capacitor electrode CE2A of a rectangle having the longer side in the vertical direction, and the third capacitor electrode CE3A of a rectangle having the longer side in the lateral direction. The active region AR41 is arranged in the center part of the first capacitor electrode CE1A, and the active regions AR42, AR43 are arranged in both sides of the active region AR41. As described above, the active regions AR42, AR43 are regions for supplying desired potential to the n-type well NW2 that forms the first capacitor electrode CE1A.

In the X direction and the Y direction of the paper surface of FIG. 3A, the second capacitor electrode CE2A is arranged so as to fully cover the active region AR41, and the third capacitor electrode CE3A is formed over the second capacitor electrode CE2A so as to fully cover the active region AR41. The second capacitor electrode CE2A has projected sections that do not overlap with the active region AR41 and the third capacitor electrode CE3A in the Y direction. The third capacitor electrode CE3A has projected sections that do not overlap with the active region AR41 and the second capacitor electrode CE2A in the X direction. Also, the essential part cross-sectional view of the laminated type capacitor element CS of FIG. 2 expresses the cross section along the line A-A of FIG. 3.

As shown in FIG. 3B, the laminated type capacitor element CS has a structure of coupling the first capacitor C1 and the second capacitor CS2 in parallel. The first capacitor C1 includes the first capacitor electrode CE1A and the second capacitor electrode CE2A, and the second capacitor C2 includes the second capacitor electrode CE2A and the third capacitor electrode CE3A. The second capacitor electrode CE2A is common to the first capacitor C1 and the second capacitor C2, the first capacitor electrode CE1A of the first capacitor C1 and the third capacitor electrode CE3A of the second capacitor C2 are electrically coupled, and thereby parallel coupling is formed. The first capacitor C1 and the second capacitor C2 are not necessarily required to be coupled in parallel, the both may be coupled in series, and each of them may be used individually.

Next, the configurations over the memory cell MC1 formed in the memory cell region 1A, over the MISFET QH formed in the peripheral circuit region 1B, over the MISFET QL formed in the peripheral circuit region 1C, and over the laminated type capacitor element CS formed in the peripheral circuit region 1D will be explained specifically.

Over the semiconductor substrate 1, an insulation film 14 is formed so as to cover the cap insulation film CP2, the gate insulation film GIm, the memory gate electrode MG, the gate electrode GEH, the gate electrode GEL, the second capacitor electrode CE2A, and the side wall spacer SW. The insulation film 14 is configured of a silicon nitride film and the like for example.

Over the insulation film 14, an interlayer insulation film 15 is formed. The interlayer insulation film 15 is configured of a single film of a silicon oxide film, a laminated film of a silicon nitride film and a silicon oxide film, and the like. The upper surface of the interlayer insulation film 15 is flattened.

Contact holes CNT are formed in the interlayer insulation film 15, and conductive plugs PG, PG1, PG2, and PG3 are embedded as conductor sections in the contact holes CNT.

The plugs PG, PG1, PG2, and PG3 are configured of thin barrier conductor films formed in the bottom part and over the side wall or over the side surface of the contact holes CNT, and main conductor films formed over the barrier conductor films so as to fill up the contact holes CNT. In FIG. 2, for simplification of the drawing, the barrier conductor film and the main conductor film forming the plugs PG, PG1, PG2, and PG3 are illustrated integratedly. Also, the barrier conductor film forming the plugs PG, PG1, PG2, and PG3 can be formed of a titanium (Ti) film, a Titanium nitride (TiN) film, or a laminated film thereof for example, and the main conductor film forming the plugs PG, PG1, PG2, and PG3 can be formed of a tungsten (W) film.

The contact holes CNT and the plugs PG, PG1, PG2, and PG3 embedded therein are formed over the n⁺ type semiconductor regions 12a, 12b, 12d, and 12e, over the p⁺ type semiconductor region 12c, over the second capacitor electrode CE2A, over the third capacitor electrode CE3A, and the like, and are electrically coupled.

Over the interlayer insulation film 15 where the plug PG is embedded, wiring of the first layer as damascene wiring as embedded wiring whose main conductive material is copper (Cu) for example is formed. Over the wiring of the first layer, although wiring of an upper layer is also formed as damascene wiring, illustration and explanation thereof will be omitted here. Also, the wiring of the first layer and the wiring of the layer thereupper are not limited to the damascene wiring, can be formed by patterning of a conductor film for wiring, and can also be formed of tungsten (W) wiring, aluminum (Al) wiring or the like for example.

<Method for Manufacturing Semiconductor Device>

Next, a method for manufacturing a semiconductor device of the present first embodiment will be explained.

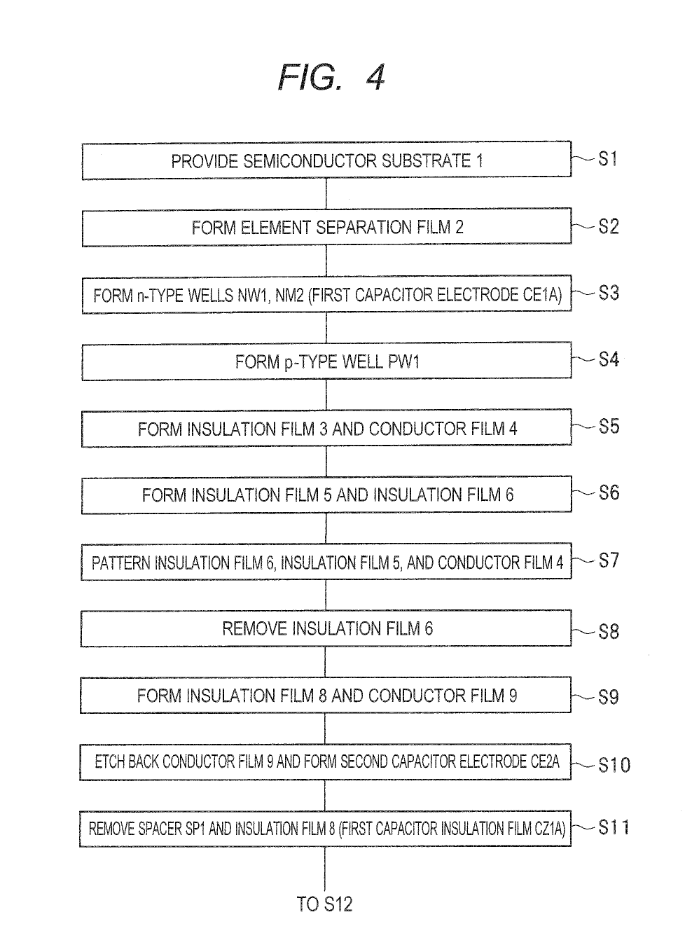

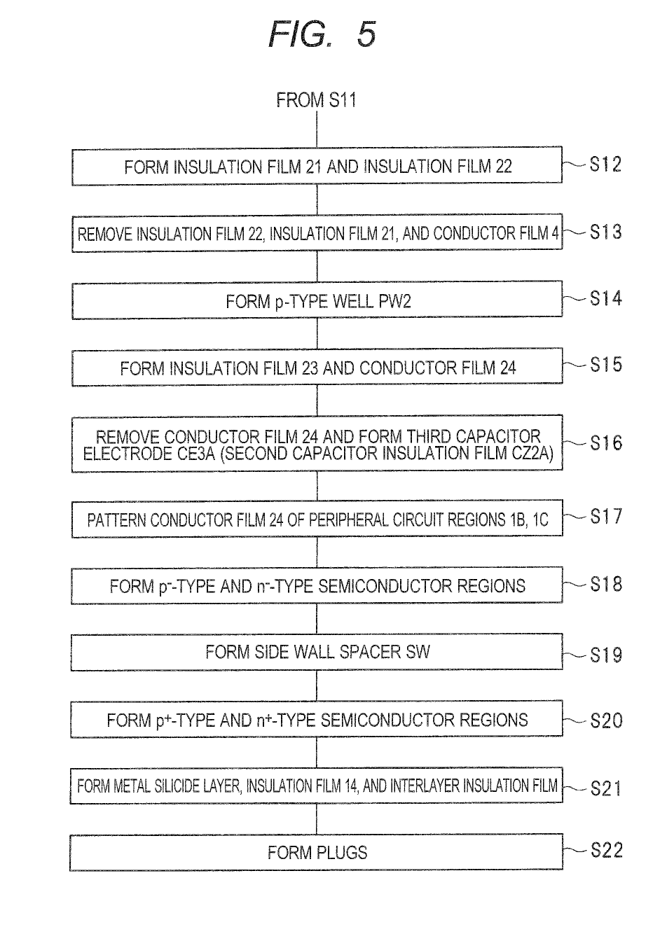

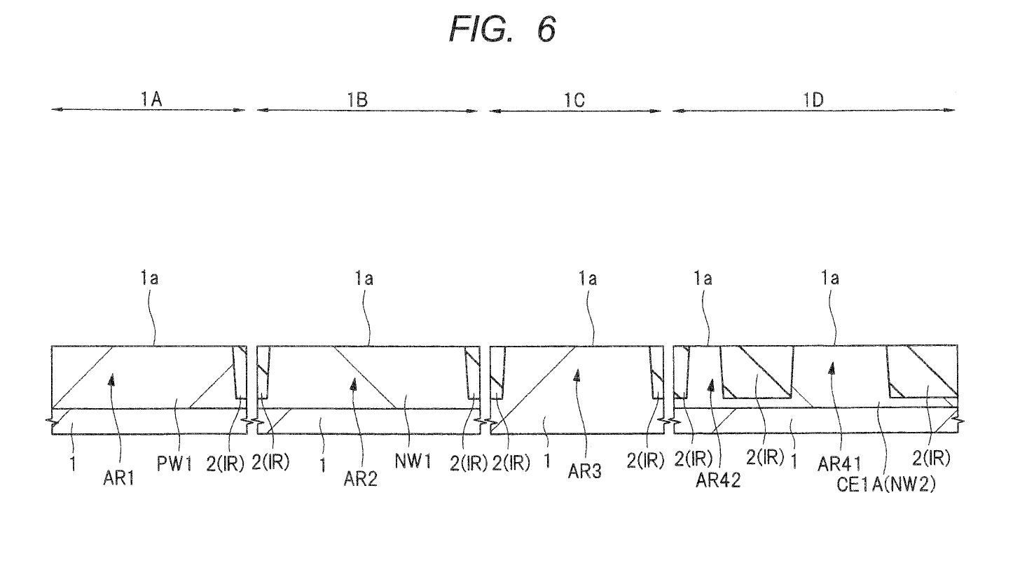

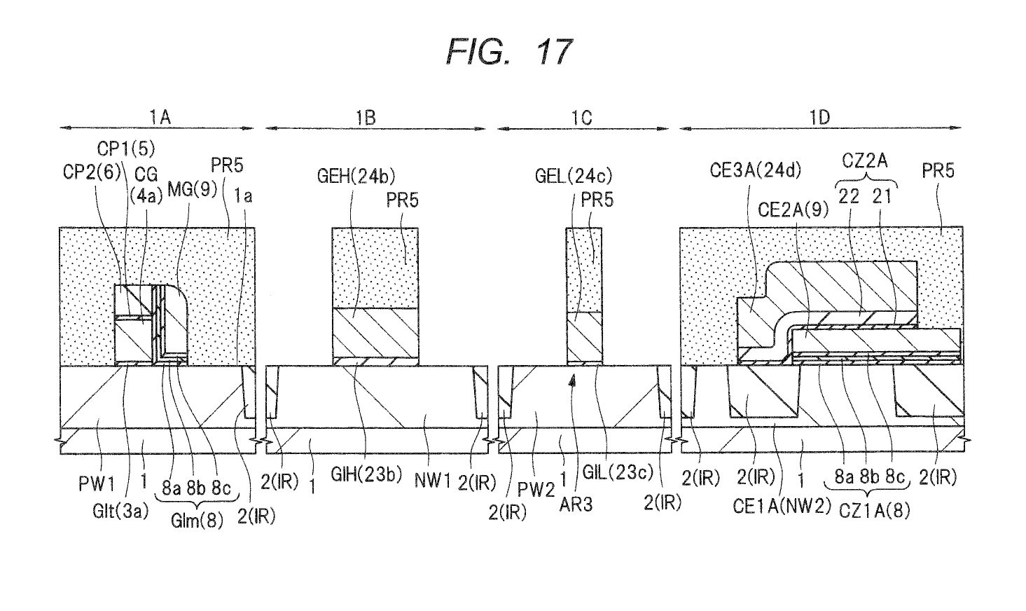

FIG. 4 and FIG. 5 are process flow charts showing a part of a manufacturing step of the semiconductor device of the first embodiment. FIG. 6-FIG. 20 are essential part cross-sectional views during a manufacturing step of the semiconductor device of the first embodiment. In the cross-sectional views of FIG. 6-FIG. 20, the essential part cross-sectional views of the memory cell region 1A and the peripheral circuit regions 1B, 1C and 1D are illustrated, and the states the memory cell MC1 is formed in the memory cell region 1A, the MISFET QH is formed in the peripheral circuit region 1B, the MISFET QL is formed in the peripheral circuit region 1C, and the laminated type capacitor element CS is formed in the peripheral circuit region 1D respectively are illustrated.

Also, in the present first embodiment, a case the control transistor CT and the memory transistor MT of n-channel type are formed in the memory cell region 1A is explained, however, by reversing the conductivity type, it is also possible to form the control transistor CT and the memory transistor MT of p-channel type in the memory cell region 1A.

In a similar manner, in the present first embodiment, a case the MISFET QH of p-channel type is formed in the peripheral circuit region 1B is explained, however, by reversing the conductivity type, it is also possible to form the MISFET QH of n-channel type in the peripheral circuit region 1B, and it is also possible to form a CMISFET (Complementary MISFET) and the like in the peripheral circuit region 1B. Further, in a similar manner, in the present first embodiment, a case the MISFET QL of n-channel type is formed in the peripheral circuit region 1C is explained, however, by reversing the conductivity type, it is also possible to form the MISFET QL of p-channel type in the peripheral circuit region 1C, and it is also possible to form a CMISFET and the like in the peripheral circuit region 1C.

As shown in FIG. 6, first, the semiconductor substrate 1 as a semiconductor wafer configured of p-type mono-crystal silicon and the like having the specific resistance of approximately 1-10 Ωcm for example is arranged or provided (step S1 of FIG. 4).

Next, as shown in FIG. 6, the element separation film 2 is formed (step S2 of FIG. 4). The element separation film 2 becomes the element separation region IR that partitions the active region AR1 in the memory cell region 1A of the main surface 1a of the semiconductor substrate 1. Also, the element separation film 2 becomes the element separation region IR that partitions the active region AR2 in the peripheral circuit region 1B of the main surface 1a of the semiconductor substrate 1, becomes the element separation region IR that partitions the active region AR3 in the peripheral circuit region 1C of the main surface 1a of the semiconductor substrate 1, and becomes the element separation regions IR that partition the active regions AR41 and AR 42 in the peripheral circuit region 1D of the main surface 1a of the semiconductor substrate 1.

The element separation film 2 is configured of an insulating material such as silicon oxide, and can be formed by the STI (Shallow Trench Isolation) method for example. The element separation film 2 can be formed for example by forming a groove for element separation in the element separation region IR, and thereafter embedding an insulation film configured of silicon oxide for example in this groove for element separation.

Next, as shown in FIG. 6, in the peripheral circuit regions 1B and 1D, the n-type wells NW1 and NW2 are formed in the active regions AR2, AR41, and AR42 (step S3 of FIG. 4). The n-type wells NW1 and NW2 can be formed by introducing n-type impurity such as phosphorus (P) for example into the semiconductor substrate 1 by the ion implantation method and the like. The n-type wells NW1 and NW2 are formed over a predetermined depth from the main surface 1a of the semiconductor substrate 1 so as to be deeper than the groove for element separation. In other words, the n-type wells NW1 and NW2 are also formed in a part lower than the element separation film 2. The n-type well NW2 becomes the first capacitor electrode CE1A of the laminated type capacitor element CS.

Next, as shown in FIG. 6, in the memory cell region 1A, the p-type well PW1 is formed in the active region AR41 (step S4 of FIG. 4). The p-type well PW1 can be formed by introducing p-type impurity such as boron (B) for example into the semiconductor substrate 1 by the ion implantation method and the like. The p-type well PW1 is formed over a predetermined depth from the main surface 1a of the semiconductor substrate 1. Also, the order of step S3 and step S4 may be reversed.

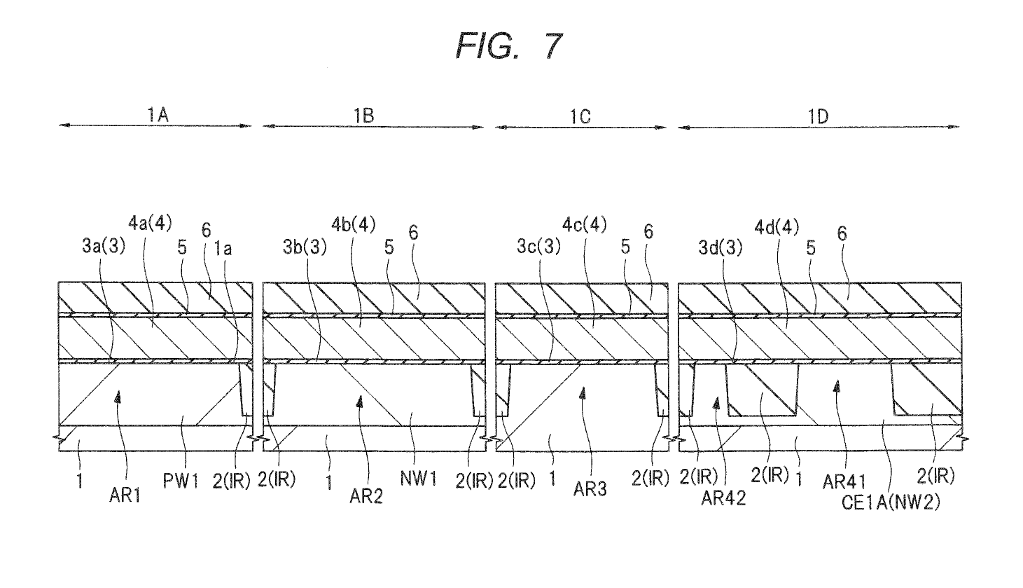

Next, as shown in FIG. 7, an insulation film 3 and a conductor film 4 are formed over the entire surface of the main surface 1a of the semiconductor substrate 1 (step S5 of FIG. 4).

In step S5, first, as shown in FIG. 7, in the memory cell region 1A and the peripheral circuit regions 1B, 1C, and 1D, the insulation film 3 is formed over the main surface 1a of the semiconductor substrate 1. Out of the insulation film 3, a portion formed in the memory cell region 1A is called the insulation film 3a, a portion formed in the peripheral circuit region 1B is called an insulation film 3b, a portion formed in the peripheral circuit region 1C is called an insulation film 3c, and a portion formed in the peripheral circuit region 1D is called an insulation film 3d. The insulation film 3a is an insulation film for the gate insulation film GIt of the memory cell MC1. Also, the insulation film 3a is formed over the p-type well PW1.

The insulation film 3 can be formed using the thermal oxidation method, sputtering method, atomic layer deposition (ALD) method, or chemical vapor deposition (CVD) method and the like.

In step S5, next, as shown in FIG. 7, in the memory cell region 1A and the peripheral circuit regions 1B, 1C, and 1D, the conductor film 4 is formed over the insulation film 3. Out of the conductor film 4, a portion formed in the memory cell region 1A is called the conductor film 4a, a portion formed in the peripheral circuit region 1B is called a conductor film 4b, a portion formed in the peripheral circuit region 1C is called a conductor film 4c, and a portion formed in the peripheral circuit region 1D is called a conductor film 4d. The conductor films 4b, 4c, and 4d are formed in the same layer of the conductor film 4a. The conductor film 4a is a conductor film for the control gate electrode CG of the memory cell MC1.

It is preferable that the conductor film 4 is configured of a polysilicon film. Such conductor film 4 can be formed using the CVD method and the like. The film thickness of the conductor film 4 can be made a thickness of a sufficient degree to cover the insulation film 3. Further, in forming the conductor film 4, it is also possible to form the conductor film 4 as an amorphous silicon film, and converting the amorphous silicon film to the polysilicon film in heat treatment thereafter.

As the conductor film 4, it is preferable to use one whose electrical resistivity is lowered by introducing the n-type impurity such as phosphorus (P) or arsenic (As) for example or the p-type impurity such as boron (B).

Next, as shown in FIG. 7, the insulation film 5 and the insulation film 6 are formed over the entire surface of the main surface 1a of the semiconductor substrate 1 or over the conductor film 4 (step S6 of FIG. 4).

In step S6, first, as shown in FIG. 7, in the memory cell region 1A and the peripheral circuit regions 1B, 1C, and 1D, the insulation film 5 is formed over the conductor film 4. This insulation film 5 is an insulation film for the cap insulation film CP1.

By thermal oxidation of the surface of the conductor film 4 configured of a polysilicon film for example, the insulation film 5 configured of a silicon oxide film having the thickness of approximately 6 nm for example can be formed. Or otherwise, the insulation film 5 configured of a silicon oxide film can be formed also using the CVD method instead of thermal oxidation of the surface of the conductor film 4 configured of a polysilicon film.

In step S6, next, as shown in FIG. 7, in the memory cell region 1A and the peripheral circuit regions 1B, 1C, and 1D, the insulation film 6 is formed over the insulation film 5. The insulation film 6 configured of a silicon nitride film for example can be formed using the CVD method and the like for example.

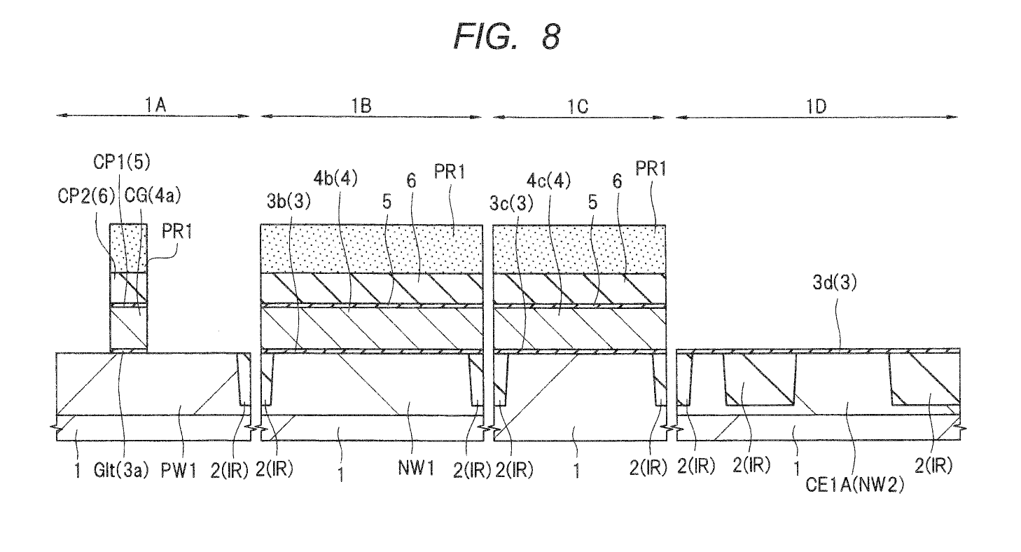

Next, as shown in FIG. 8, the insulation film 6, the insulation film 5, and the conductor film 4 are patterned (step S7 of FIG. 4). In this step S7, the insulation film 6, the insulation film 5, and the conductor film 4 are patterned using photolithography and etching for example.

First, a resist film PR1 is formed over the insulation film 6. The resist film PR1 has a pattern covering a region scheduled to form the control gate electrode CG out of the memory cell region 1A, and exposing the other portions. Also, the resist film PR1 has a pattern covering the peripheral circuit regions 1B and 1C, and exposing the peripheral circuit region 1D.

Next, using the resist film PR1 as an etching mask, the insulation film 6, the insulation film 5, and the conductor film 4 are etched and patterned by anisotropic dry etching and the like for example. Thus, in the memory cell region 1A, the control gate electrode CG configured of the conductor film 4a is formed, and the gate insulation film GIt configured of the insulation film 3a between the control gate electrode CG and the p-type well PW1 of the semiconductor substrate 1 is formed. In other words, the control gate electrode CG is formed over the p-type well PW1 of the semiconductor substrate 1 through the gate insulation film GIt in the memory cell region 1A.

Also, the cap insulation film CP1 configured of the insulation film 5 of a portion formed over the control gate electrode CG is formed, and the cap insulation film CP2 configured of the insulation film 6 of a portion formed over the control gate electrode CG through the cap insulation film CP1 is formed. On the other hand, in the peripheral circuit regions 1B and 1C, the insulation film 6, the insulation film 5, and the conductor film 4 are left. The conductor film 4b is left in the peripheral circuit region 1B, and the conductor film 4c is left in the peripheral circuit region 1C. The insulation film 6, the insulation film 5, and the conductor film 4d are removed in the peripheral circuit region 1D. Thereafter, the resist pattern or the resist film PR1 is removed.

Also, in the memory cell region 1A, the insulation film 3a of a portion not covered by the control gate electrode CG can possibly be removed by performing dry etching of step S7 or by performing wet etching after dry etching of step S7. Further, in a portion where the control gate electrode CG is not formed out of the memory cell region 1A, the p-type well PW1 of the semiconductor substrate 1 is exposed. In the peripheral circuit region 1D, in a similar manner, the insulation film 3d also can possibly be removed by performing dry etching of step S7 or by performing wet etching after the dry etching.

Further, although illustration will be omitted, in step S7, it is also possible to form the control gate electrode CG and the cap insulation film CP1, and thereafter to introduce n-type impurity to the p-type well PW1 by the ion implantation method using the cap insulation film CP1 and the control gate electrode CG as masks.

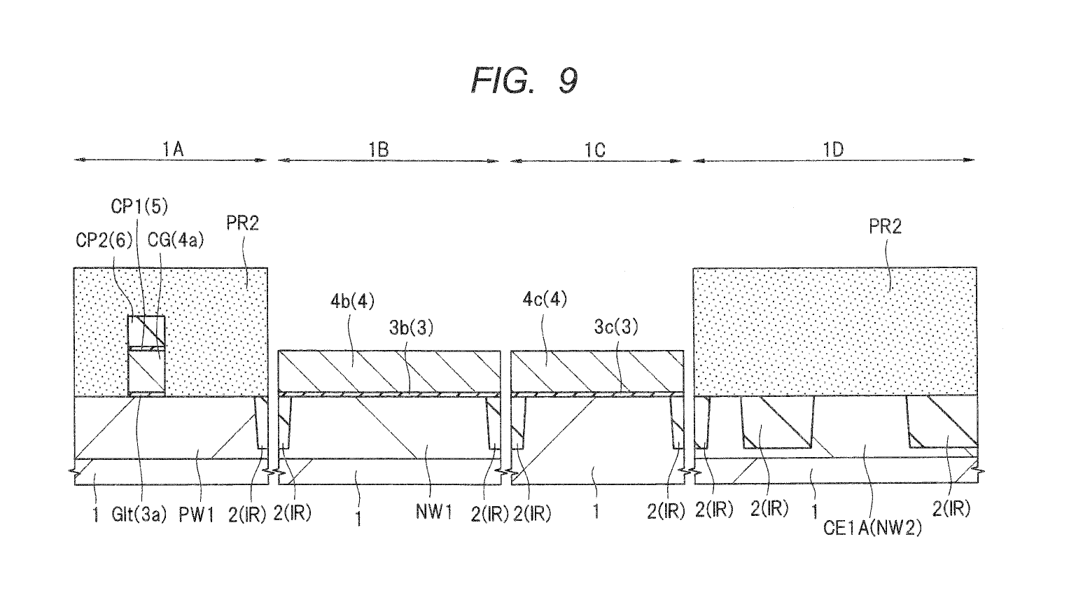

Next, as shown in FIG. 9, in the peripheral circuit regions 1B and 1C, the insulation films 6 are removed (step S8 of FIG. 4).

In this step S8, first, in the memory cell region 1A, a resist film PR2 is formed so as to cover the cap insulation film CP2 and the control gate electrode CG, and so as to cover the peripheral circuit region 1D. The resist film PR2 has a pattern of covering the memory cell region 1A and the peripheral circuit region 1D and exposing the peripheral circuit regions 1B and 1C.

Next, the insulation films 6 are etched by dry etching and the like for example and are removed using the resist pattern as a mask. Thus, as shown in FIG. 9, the insulation films 6 of the portions left in the peripheral circuit regions 1B and 1C can be removed entirely. Thereafter, the resist films or the resist patterns of the portions left in the memory cell region 1A and the peripheral circuit region 1D are removed.

Also, as shown in FIG. 9, because the film thickness of the insulation film 5 is thinner compared to the film thickness of the insulation film 6, in etching and removing the insulation films 6 of the portions left in the peripheral circuit regions 1B and 1C, the insulation films 5 of the portions left in the peripheral circuit regions 1B and 1C are also removed.

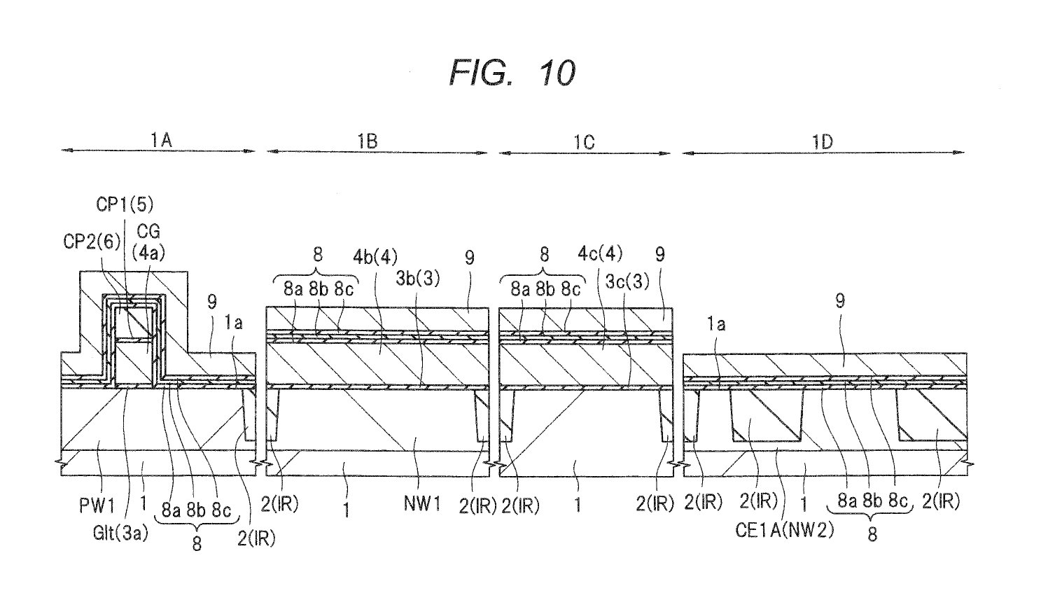

Next, as shown in FIG. 10, the insulation films 8 and the conductor films 9 are formed (step S9 of FIG. 4).

In step S9, first, as shown in FIG. 10, in the memory cell region 1A and the peripheral circuit regions 1B, 1C, and 1D, the insulation films 8 for the gate insulation film GIm of the memory transistor MT are formed over the main surface 1a of the semiconductor substrate 1. At this time, in the memory cell region 1A, the insulation film 8 is formed over the main surface 1a of the semiconductor substrate 1 of the exposed portion, the side surface of the control gate electrode CG, and the upper surface and the side surface of the cap insulation film CP2. Also, the insulation films 8 are formed over the upper surface and the side surface of the conductor films 4 of the portions left in the peripheral circuit regions 1B and 1C. Further, in the peripheral circuit region 1D, the insulation film 8 is formed over the main surface 1a of the semiconductor substrate 1. In other words, the insulation films 8 are formed so as to cover the main surface 1a of the semiconductor substrate 1, the side surface of the control gate electrode CG, the surface of the cap insulation film CP2, the surface of the conductor films 4 of the portions left in the peripheral circuit regions 1B and 1C, and the main surface 1a of the semiconductor substrate 1 of the peripheral circuit region 1D.

The insulation film 8 is an insulation film including an electric charge accumulation section in the inside as described above, and is configured of the laminated films of the silicon oxide film 8a, the silicon nitride film 8b, and the silicon oxide film 8c formed in order from the bottom as the insulation film.

Out of the insulation film 8, the silicon oxide film 8a can be formed by the thermal oxidation method or the ISSG oxidation method and the like at a temperature of approximately 1,000-1,100° C. for example. Also, out of the insulation film 8, the silicon nitride film 8b can be formed by the CVD method for example. Further, out of the insulation film 8, the silicon oxide film 8c can be formed by the CVD method for example.

The silicon oxide film 8a is formed by the thermal oxidation method or the ISSG oxidation method for example. At this time, the main surface 1a of the semiconductor substrate 1 of the exposed portion, the side surface of the control gate electrode CG, the upper surface and the side surface of the conductor films 4 of the portions left in the peripheral circuit regions 1B and 1C, and the main surface 1a of the semiconductor substrate 1 of the peripheral circuit region 1D are oxidized.

Next, the silicon nitride film 8b is formed over the silicon oxide film 8a by the CVD method for example, and the silicon oxide film 8c with a dense film quality is formed over the silicon nitride film 8b by the high temperature CVD method of approximately 800° C. for example. Thereby, the insulation film 8 configured of the laminated film of the silicon oxide film 8a, the silicon nitride film 8b, and the silicon oxide film 8c can be formed. Thus, the silicon oxide films 8a and 8c are formed at a comparatively high temperature to achieve the dense film quality.

The insulation film 8 formed in the memory cell 1A functions as a gate insulation film of the memory gate electrode MG, and has an electric charge holding function. The insulation film 8 has a structure of embracing the silicon nitride film 8b as an electric charge accumulation section by the silicon oxide film 8a and the silicon oxide film 8c as electric charge blocking layers. Also, the potential barrier height of the electric charge blocking layers configured of the silicon oxide films 8a and 8c becomes higher compared to the potential barrier height of the electric charge accumulation section configured of the silicon nitride film 8b.

Further, although the silicon nitride film 8b is used as an insulation film having the trap level in the present first embodiment, use of the silicon nitride film 8b is preferable in terms of reliability. However, the insulation film having the trap level is not limited to a silicon nitride film, and an aluminum oxide (alumina) film, a hafnium oxide film, a tantalum oxide film, or the like for example can be used which is a high dielectric constant film having the dielectric constant higher than that of a silicon nitride film.

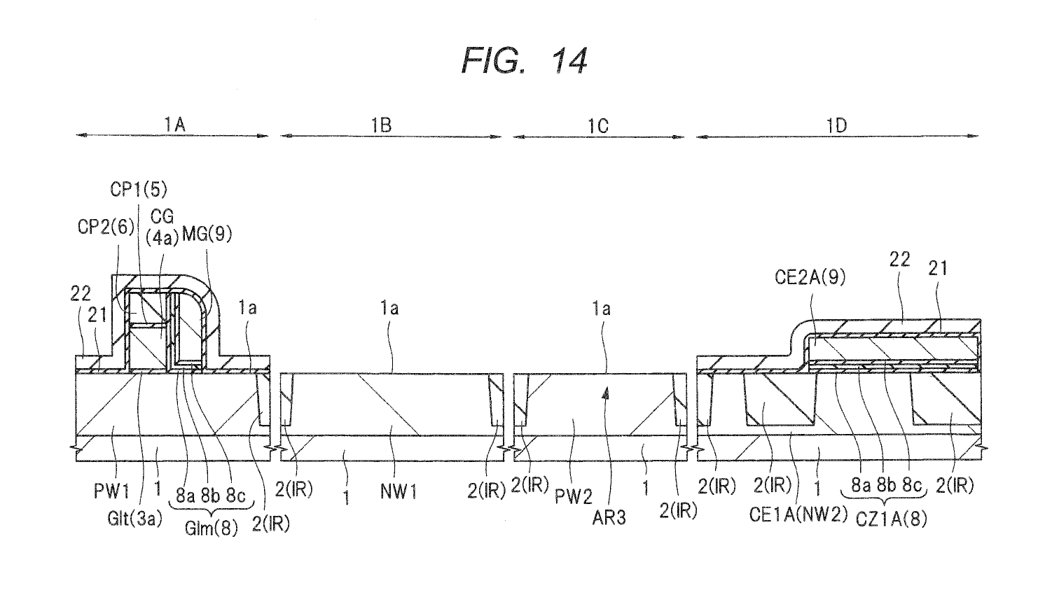

In the present first embodiment, after performing the step for forming the insulation film 8 out of step S9, the conductor films 4 of the portions left in the peripheral circuit regions 1B and 1C are removed, and the p-type well PW2 (refer to FIG. 14 described below) is formed in the peripheral circuit region 1C. As described above, the step for forming the insulation film 8 is performed at a high temperature of approximately 1,000-1,100° C. for example. Therefore, in the present first embodiment in which the p-type well PW2 is formed after forming the insulation film 8, the n-type impurity having been introduced to the p-type well PW2 can be prevented from diffusing at a high temperature in forming the insulation film 8. Also, the concentration distribution of the impurity in the p-type well PW2 can be prevented from changing.

In the peripheral circuit region 1D, the laminated layer film configured of the silicon oxide film 8a, the silicon nitride film 8b, and the silicon oxide film 8c is a film that becomes the first capacitor insulation film CZ1A of the laminated type capacitor element CS.

In step S9, next, as shown in FIG. 10, in the memory cell region 1A and the peripheral circuit regions 1B, 1C, and 1D, the conductor films 9 are formed over the insulation films 8.

It is preferable that the conductor film 9 is configured of a polysilicon film for example. Such conductor film 9 can be formed using the CVD method and the like. Further, in forming the conductor film 9, it is also possible to form the conductor film 9 as an amorphous silicon film, and to convert the amorphous silicon film to a polysilicon film in heat treatment thereafter.

As the conductor film 9, it is preferable to use one whose electrical resistivity is lowered by introducing the n-type impurity such as phosphorus (P) or arsenic (As) for example or the p-type impurity such as boron (B).

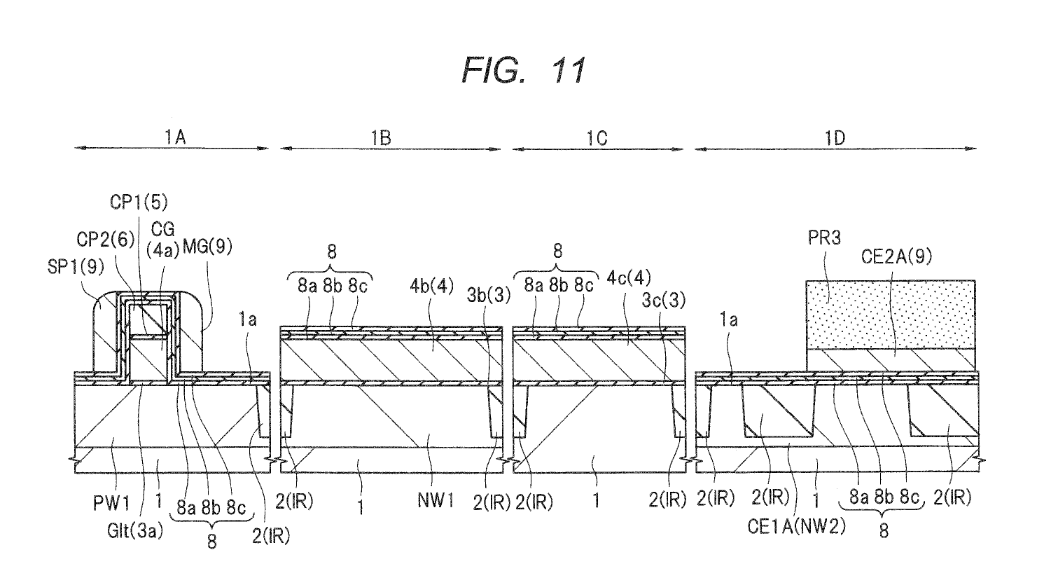

Next, as shown in FIG. 11, the conductor films 9 are etched back by the anisotropic dry etching technology, and the memory gate electrode MG and the second capacitor electrode CE2A are formed (step S10 of FIG. 4).

In this step S10, first, a resist film PR3 is formed using photolithography. The resist film PR3 has a pattern of covering a portion where the second capacitor electrode CE2A of the peripheral circuit region 1D is formed, and exposing the other portions. Also, the resist film PR3 has a pattern of exposing the memory cell region 1A and the peripheral circuit regions 1B and 1C. Next, the conductor film 9 is etched back by subjecting the conductor film 9 to anisotropic dry etching, the conductor film 9 is left in a side wall spacer shape over the side walls or over the side surfaces of both sides of the control gate electrode CG through the insulation film 8, and thereby the memory gate electrode MG is formed. In this etching back, the conductor films 9 of the peripheral circuit regions 1B and 1C are removed. Also, in the peripheral circuit region 1D, the conductor film 9 is left only in a portion covered by the resist film PR3, and the second capacitor electrode CE2A is formed.

Thus, as shown in FIG. 11, in the memory cell region 1A, over a side wall of one side which is the side the control gate electrode CG and the adjacent memory gate electrode MG are arranged out of the side walls of both sides of the control gate electrode CG, the memory gate electrode MG configured of the conductor film 9 that is left in a side wall spacer shape is formed through the insulation film 8. Also, over a side wall of the opposite side of the first side which is the opposite side of the side the control gate electrode CG and the adjacent memory gate electrode MG are arranged out of the side walls of both sides of the control gate electrode CG, a spacer SP1 configured of the conductor film 9 that is left in a side wall spacer shape is formed through the insulation film 8.

Over the control gate electrode CG, the cap insulation film CP2 is formed through the cap insulation film CP1. Therefore, the memory gate electrode MG is configured of the conductor film 9 left in a side wall spacer shape over the side wall of the first side of the cap insulation film CP2 through the insulation film 8. Also, the spacer SP1 is configured of the conductor film 9 left in a side wall spacer shape over the side wall on the opposite side of the first side of the cap insulation film CP2 through the insulation film 8.

Between the memory gate electrode MG formed in step S10 and the p-type well PW1 of the semiconductor substrate 1 and between the memory gate electrode MG and the control gate electrode CG, the insulation film 8 is interposed, and this memory gate electrode MG is configured of the conductor film 9 that contacts the insulation film 8.

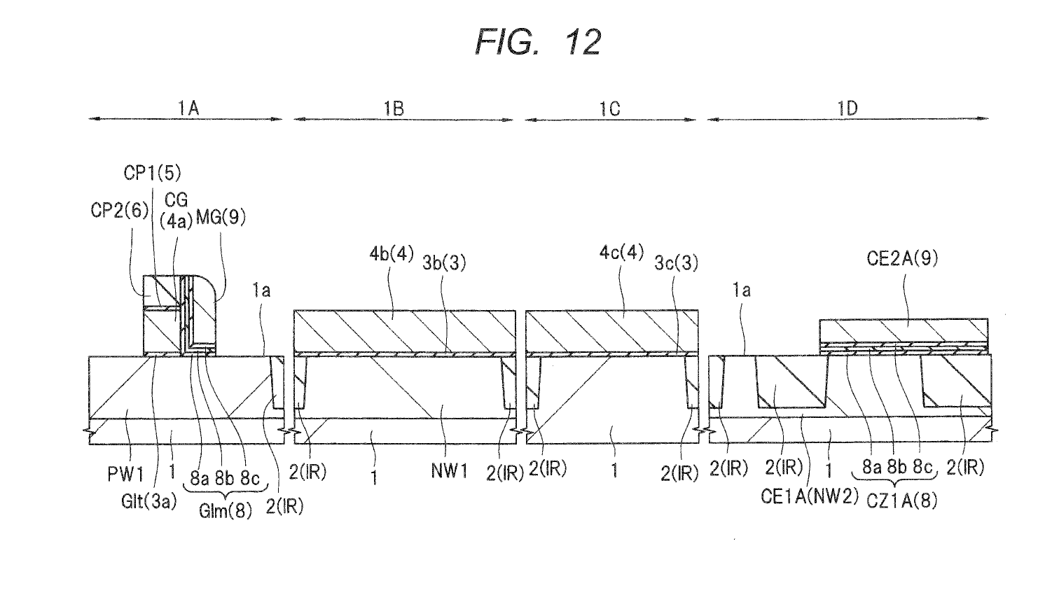

At the stage the etch back step of step S10 has been performed, the portions of the insulation films 8 not covered by both of the memory gate electrode MG and the spacer SP1, which is the insulation films 8 of the portions not covered by both of the memory gate electrode MG and the spacer SP1, are exposed. The insulation film 8 below the memory gate electrode MG in the memory cell region 1A becomes the gate insulation film GIm (refer to FIG. 12 described below) of the memory transistor MT. Also, by adjusting the film thickness of the conductor film 9 formed in step S8, the memory gate length can be adjusted.

Next, as shown in FIG. 12, the spacer SP1 and the insulation films 8 are removed (step S11 of FIG. 4).

In step S11, first, using photolithography, such a resist pattern (not illustrated) of covering the memory gate electrode MG and exposing the spacer SP1 is formed over the semiconductor substrate 1. Also, the spacer SP1 is removed by dry etching using the formed resist pattern as an etching mask. On the other hand, the memory gate electrode MG is left without being etched because the memory gate electrode MG has been covered by the resist pattern. Thereafter, this resist pattern is removed.

In step S11, next, the insulation films 8 of the portions not covered by the memory gate electrode MG and the second capacitor electrode CE2A are removed by etching such as wet etching for example. At this time, in the memory cell region 1A, the insulation films 8 positioned between the memory gate electrode MG and the p-type well PW1 and between the memory gate electrode MG and the control gate electrode CG are left without being removed, and the insulation films 8 positioned in the other regions are removed. At this time, in the memory cell region 1A, the gate insulation films GIm configured of the insulation films 8 of the portion left between the memory gate electrode MG and the p-type well PW1 and the portion left between the memory gate electrode MG and the control gate electrode CG are formed. Also, in the peripheral circuit region 1D, the first capacitor insulation film CZ1A configured of the insulation film 8 is formed between the second capacitor electrode CE2A and the n-type well NW2.

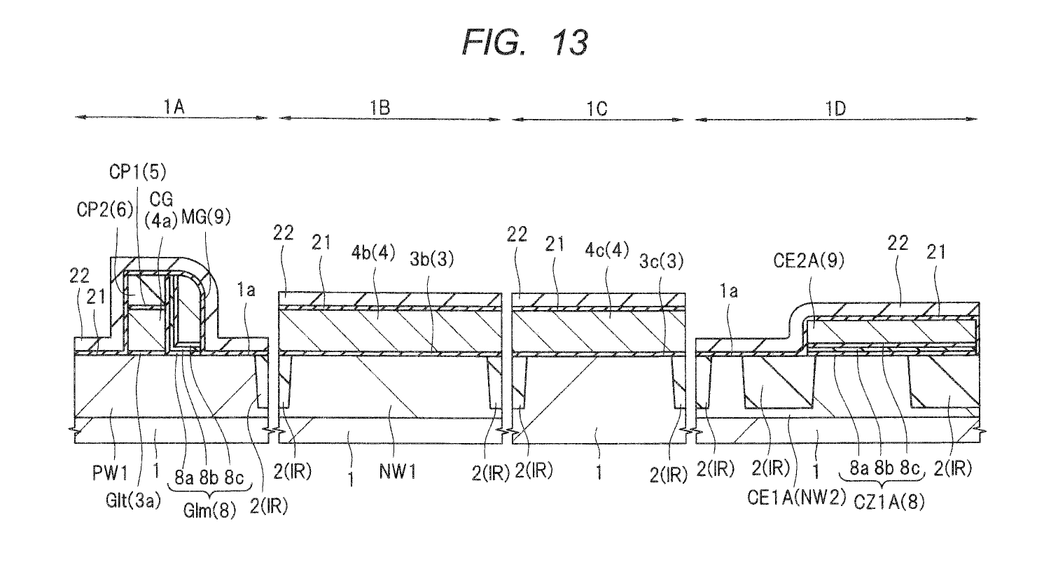

Next, as shown in FIG. 13, insulation films 21 and insulation films 22 are formed (step S12 of FIG. 5).

In step S12, first, in the memory cell region 1A and the peripheral circuit regions 1B, 1C, and 1D, the insulation films 21 are formed in the main surface 1a of the semiconductor substrate 1. At this time, in the memory cell region 1A, the insulation film 21 is formed so as to cover the main surface 1a of the semiconductor substrate 1 of the exposed portion, the control gate electrode CG, the cap insulation film CP2, and the memory gate electrode MG. Also, the insulation films 21 are formed so as to cover the conductor film 4 of the portion left in the peripheral circuit region 1B which is the conductor film 4b and the conductor film 4 of the portion left in the peripheral circuit region 1C which is the conductor film 4c, and so as to cover the main surface 1a of the semiconductor substrate 1 and the second capacitor electrode CE2A of the peripheral circuit region 1D. The insulation films 21 are formed by the thermal oxidation method or the ISSG oxidation method.

In step S12, next, in the memory cell region 1A and the peripheral circuit regions 1B, 1C, and 1D, the insulation films 22 are formed over the insulation films 21. The insulation films 22 configured of silicon nitride films for example can be formed using the CVD method and the like for example.

The insulation films 21 and the insulation films 22 are protection films (protecting insulation films) of the memory cell MC1, and are formed so as to cover the memory cell MC1. In the memory cell region 1A, the insulation films 21 and the insulation films 22 are formed so as to cover the control gate electrode CG, the gate insulation film GIm, the memory gate electrode MG, and the main surface 1a of the semiconductor substrate 1 (the p-type well PW1). In step S13 and onward shown in FIG. 5, although the MISFET QH is formed in the peripheral circuit region 1B and the MISFET QL is formed in the peripheral circuit region 1C, in the forming step thereof, treatments such as thermal oxidation (step S15 for example) and etching (step S13 for example) and the like are performed. The insulation films 21 and the insulation films 22 are arranged to prevent the control gate electrode CG, the memory gate electrode MG, the gate insulation films GIt and GIm, the insulation film 8, the main surface 1a of the semiconductor substrate 1, and the like already formed in the memory cell region 1A from being oxidized or etched at the time of treatment such as the thermal oxidation and etching described above.

Also, the insulation films 21 and the insulation films 22 are films that become the second capacitor insulation film CZ2A of the laminated type capacitor element CS in the peripheral circuit region 1D.

Next, as shown in FIG. 14, in the peripheral circuit regions 1B and 1C, the insulation films 22, the insulation films 21, and the conductor films 4 are removed (step S13 of FIG. 5).

In step S13, first, a resist film (illustration thereof is omitted) having a pattern of covering the memory cell region 1A and the peripheral circuit region 1D and exposing the peripheral circuit regions 1B and 1C is formed. Next, using the resist pattern as an etching mask, the insulation films 22, the insulation films 21, and the conductor films 4 are etched and removed by dry etching and the like for example. Thus, as shown in FIG. 14, the conductor films 4 of the portions left in the peripheral circuit regions 1B and 1C can be entirely removed. In other words, the conductor film 4b can be removed in the peripheral circuit region 1B, and the conductor film 4c can be removed in the peripheral circuit region 1C. Thereafter, the resist film that is the resist pattern of the portion left in the memory cell 1A is removed. In the memory cell region 1A and the peripheral circuit region 1D, the insulation films 21 and the insulation films 22 are left.

Next, as shown in FIG. 14, in the peripheral circuit region 1C, the p-type well PW2 is formed in the active region AR3 (step S14 of FIG. 5). Similarly to the p-type well PW1, the p-type well PW2 can be formed by introducing p-type impurity such as boron (B) for example into the semiconductor substrate 1 by the ion implantation method and the like. The p-type well PW2 is formed over a predetermined depth from the main surface 1a of the semiconductor substrate 1.

Next, the natural oxide film of the surface of the semiconductor substrate 1 is removed by wet etching and the like using a hydrofluoric acid (HF) aqueous solution for example, the surface of the semiconductor substrate 1 is washed, and thereby the surface of the semiconductor substrate 1 is cleaned. Thus, in the peripheral circuit regions 1B and 1C, the surface of the semiconductor substrate 1 or the surface of the n-type well NW1 and the p-type well PW2 is exposed.

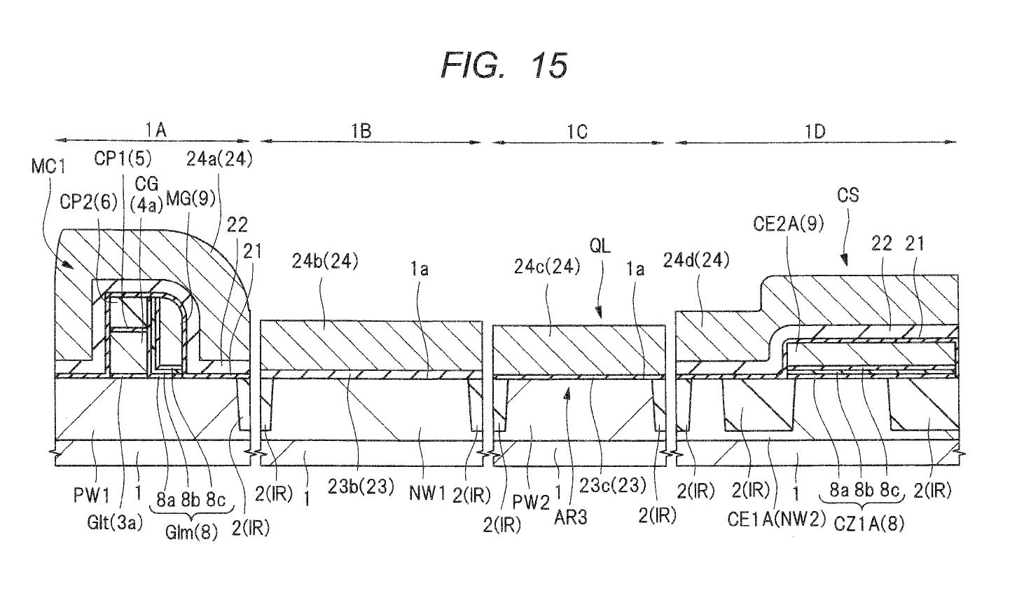

Next, as shown in FIG. 15, the insulation films 23 and the conductor films 24 are formed over the entire surface of the main surface 1a of the semiconductor substrate 1 (step S15 of FIG. 5).

In step S15, first, as shown in FIG. 15, the insulation films 23 are formed in the peripheral circuit regions 1B and 1C. Out of the insulation films 23, the portion formed in the peripheral circuit region 1B is called the insulation film 23b, and the portion formed in the peripheral circuit region 1C is called the insulation film 23c. The insulation film 23b is an insulation film for the gate insulation film GIH of the MISFET QH, and the insulation film 23c is an insulation film for the gate insulation film GIL of the MISFET QL. Therefore, the film thickness of the insulation film 23b is thicker than the film thickness of the insulation film 23c. Also, the insulation film 23b is formed over the n-type well NW1, and the insulation film 23c is formed over the p-type well PW2.

The insulation films 23b and 23c can be formed by the thermal oxidation method for example. In this case, although the insulation films 23b and 23c are configured of a silicon oxide film, it is also possible that the silicon oxide film is subjected to nitriding to obtain an oxynitride film. Also, for example, the insulation film 23c may be formed by the ISSG oxidation method, and, in this case, the surface of the insulation film 22 configured of the oxynitride film of the peripheral circuit region 1D is oxidized, and a silicon oxide film (not illustrated) is formed. Although the insulation films 21 and 22 of the peripheral circuit region 1D become the second capacitor insulation film CZ2A as described above, because a dense silicon oxide film is formed over the surface of the insulation film 22 configured of a silicon nitride film, electric charge leakage of the second capacitor insulation film CZ2A can be reduced.

In step S15, next, as shown in FIG. 15, in the memory cell region 1A and the peripheral circuit regions 1B, 1C, and 1D, the conductor films 24 are formed over the semiconductor substrate 1. Out of the conductor films 24, a portion formed in the memory cell region 1A is called the conductor film 24a, a portion formed in the peripheral circuit region 1B is called the conductor film 24b, a portion formed in the peripheral circuit region 1C is called the conductor film 24c, and a portion formed in the peripheral circuit region 1D is called the conductor film 24d. The conductor films 24a, 24b, 24c, and 24d are formed in a same layer. The conductor film 24b is a conductor film for the gate electrode GEH of the MISFET QH, and the conductor film 24c is a conductor film for the gate electrode GEL of the MISFET QL.

It is preferable that the conductor film 24 is configured of a polysilicon film. Such conductor film 24 can be formed using the CVD method and the like. Further, in forming the conductor film 24, it is also possible to form the conductor film 4 as an amorphous silicon film, and to convert the amorphous silicon film to a polysilicon film in heat treatment thereafter.

As the conductor film 24, it is preferable to use one whose electrical resistivity is lowered by introducing the n-type impurity such as phosphorus (P) or arsenic (As) for example or the p-type impurity such as boron (B). For example, it is preferable to introduce the p-type impurity to the conductor film 24b of the peripheral circuit region 1B, and to introduce the n-type impurity to the conductor film 24c of the peripheral circuit region 1C.

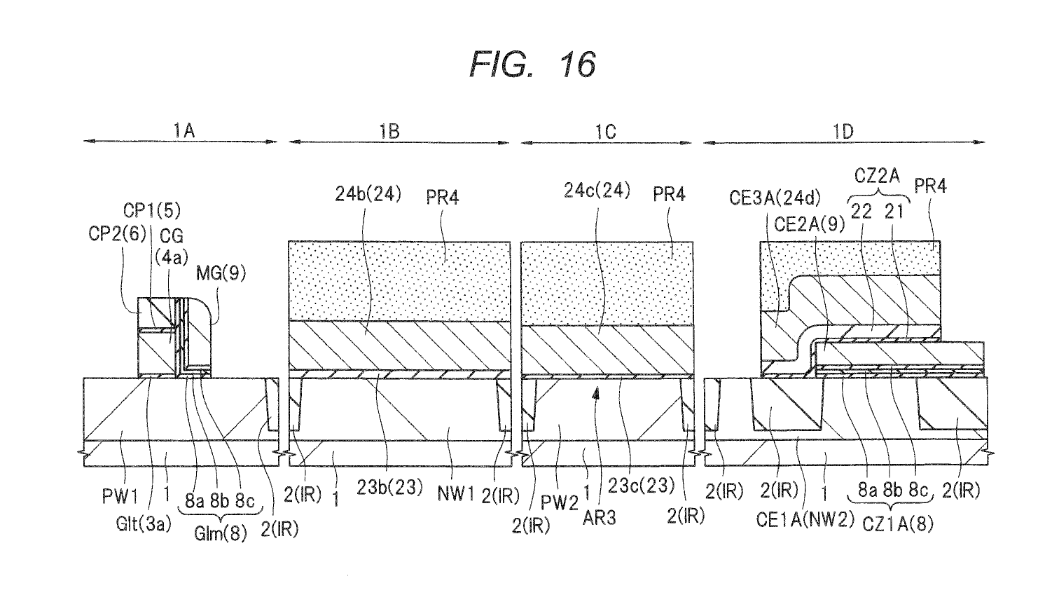

Next, as shown in FIG. 16, the conductor film 24 is removed in the memory cell 1A, and the third capacitor electrode CE3A is formed in the peripheral circuit region 1D (step S16 of FIG. 5).

In step S16, first, a resist film PR4 is formed which has a pattern of exposing the memory cell 1A, covering the peripheral circuit regions 1B and 1C, covering an area for forming the third capacitor electrode CE3A in the peripheral circuit region 1D, and exposing the other areas.

Next, the conductor film 24 is etched and removed by dry etching and the like for example using the resist film PR4 as an etching mask. Thus, as shown in FIG. 16, the conductor film 24 of a portion left in the memory cell region 1A which is the conductor film 24a is removed, and the insulation films 22 and 21 are also removed. In the peripheral circuit region 1D, by patterning the conductor film 24d and the insulation films 22 and 21 using the resist film PR4, the third capacitor electrode CE3A and the second capacitor insulation film CZ2A can be formed. Thereafter, the resist films PR4 of the portions left in the peripheral circuit regions 1B and 1C are removed.

Next, in the peripheral circuit regions 1B and 1C, the conductor films 24 are patterned (step S17 of FIG. 5).

First, a resist film PR5 is formed over the main surface 1a of the semiconductor substrate 1. The resist film PR5 has a pattern of covering the memory cell 1A and the peripheral circuit region 1D, covering an area for forming the gate electrode GEH and exposing the other portions in the peripheral circuit region 1B, and covering an area for forming the gate electrode GEL and exposing the other portions in the peripheral circuit region 1C.

Next, the conductor film 24 is etched and patterned by anisotropic dry etching and the like for example using the resist film PR5.

Thus, in the peripheral circuit region 1B, the gate electrode GEH configured of the conductor film 24b is formed, and the gate insulation film GIH configured of the insulation film 23b between the gate insulation film GEH and the n-type well NW1 of the semiconductor substrate 1 is formed.

Also, in the peripheral circuit region 1C, the gate electrode GEL configured of the conductor film 24c is formed, and the gate insulation film GIL configured of the insulation film 23c between the gate electrode GEL and the p-type well PW2 of the semiconductor substrate 1 is formed. Thereafter, the resist films PR5 are removed.

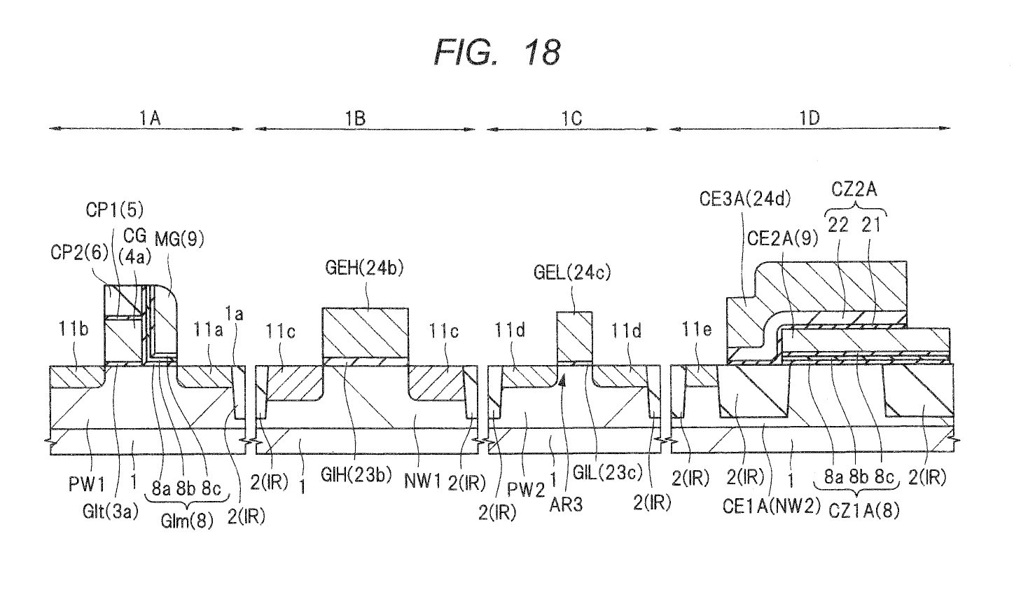

Next, as shown in FIG. 18, the n⁻ type semiconductor regions 11a, 11b, 11d, and 11e and the p⁻ type semiconductor region 11c are formed using the ion implantation method and the like (step S18 of FIG. 5). In this step S18, the n-type impurity such as arsenic (As) or phosphorus (P) for example is introduced into the p-type wells PW1, PW2, and NW2 of the semiconductor substrate 1 using the control gate electrode CG, the memory gate electrode MG, the gate electrode GEL, and the element separation film 2 as masks. Thus, the n⁻ type semiconductor regions 11a, 11b, 11d, and 11e are formed. Also, the p-type impurity configured of boron (B) for example is introduced into the n-type well NW1 of the semiconductor substrate 1 using the gate electrode GEH and the element separation film 2 as masks. Thus, the p⁻ type semiconductor region 11c is formed.

At this time, the n⁻ type semiconductor region 11a is formed so as to be self-aligned to the side surface of the memory gate electrode MG in the memory cell region 1A, and the n⁻ type semiconductor region 11b is formed so as to be self-aligned to the side surface of the control gate electrode CG in the memory cell region 1A. Also, the n⁻ type semiconductor region 11d is formed so as to be self-aligned to the side surface of the gate electrode GEL in the peripheral circuit region 1C, and the n⁻ type semiconductor region 11e is formed so as to be self-aligned to the element separation film 2 in the peripheral circuit region 1D. Further, the p⁻ type semiconductor region 11c is formed so as to be self-aligned to the side surface of the gate electrode GEH in the peripheral circuit region 1B.

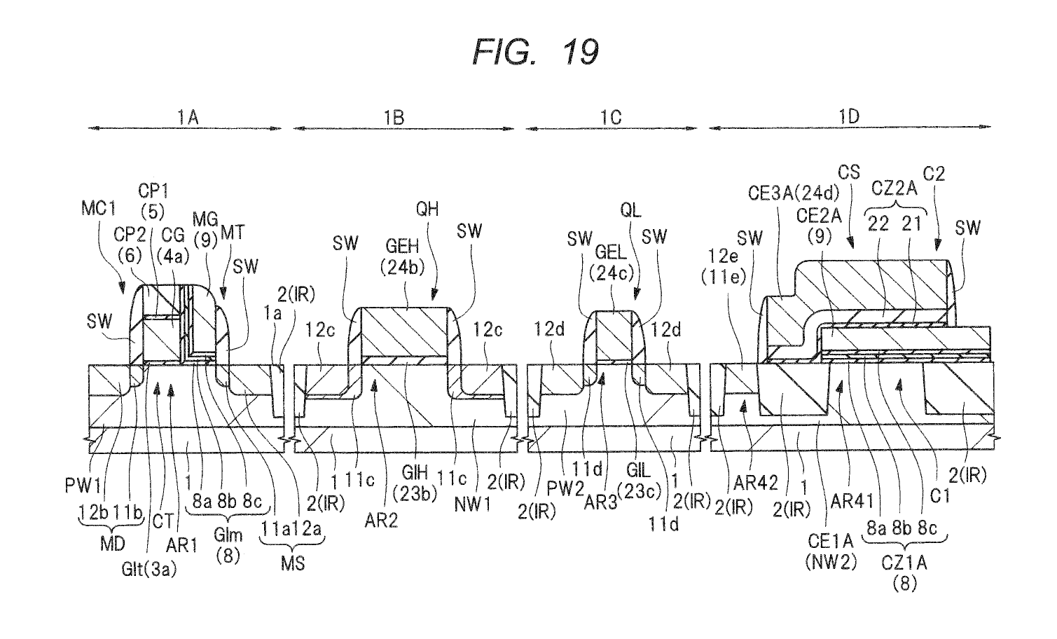

Next, as shown in FIG. 19, the side wall spacers SW are formed over the side wall of the control gate electrode CG, over the side wall of the memory gate electrode MG, over the side wall of the gate electrode GEH, over the side wall of the gate electrode GEL, and over the side wall of the third capacitor electrode CE3A (step S19 of FIG. 5).

First, an insulation film for the side wall spacers SW is formed over the entire surface of the main surface 1a of the semiconductor substrate 1, and the insulation film formed is etched back by anisotropic etching for example. Thus, this insulation film is selectively left over the side wall of the control gate electrode CG, over the side wall of the memory gate electrode MG, over the side wall of the gate electrode GEH, over the side wall of the gate electrode GEL, and over the side wall of the third capacitor electrode CE3A, and thereby the side wall spacers SW are formed. This side wall spacer SW is configured of an insulation film such as a silicon oxide film, a silicon nitride film, or a laminated film thereof.

Next, as shown in FIG. 19, the n⁺ type semiconductor regions 12a, 12b, 12d, and 12e and the p⁺ type semiconductor region 12c are formed using the ion implantation method and the like (step S20 of FIG. 5). In this step S20, the n-type impurity such as arsenic (As) or phosphorus (P) for example is introduced into the p-type wells PW1, PW2, and NW2 of the semiconductor substrate 1 using the control gate electrode CG, the memory gate electrode MG, the gate electrode GEL, the side wall spacers SW over the side walls of these electrodes, and the element separation films 2 as the masks. Thus, the n⁺ type semiconductor regions 12a, 12b, 12d, and 12e are formed. Also, the p-type impurity configured of boron (B) for example is introduced into the n-type well NW1 of the semiconductor substrate 1 using the gate electrode GEH, the side wall spacers SW formed over the side walls thereof, and the element separation film 2 as masks. Thus, the p⁺ type semiconductor region 12c is formed.

At this time, the n⁺ type semiconductor region 12a is formed in the memory cell region 1A so as to be self-aligned to the side wall spacers SW over the side walls of the memory gate electrode MG. Also, the n⁺ type semiconductor region 12b is formed in the memory cell region 1A so as to be self-aligned to the side wall spacers SW over the side walls of the control gate electrode CG. Further, the n⁺ type semiconductor region 12d is formed in the peripheral circuit region 1C so as to be self-aligned to the side wall spacers SW over the both side walls of the gate electrode GEL, and the p⁺ type semiconductor region 12c is formed in the peripheral circuit region 1B so as to be self-aligned to the side wall spacers SW over the both side walls of the gate electrode GEH. Thus, the DDD structure is formed. Also, the n⁺ type semiconductor region 12e is formed in the peripheral circuit region 1D within the n-type well NW2 so as to be self-aligned to the element separation film 2. Because the n⁺ type semiconductor region 12e is formed deeper than the n⁻ type semiconductor region 11e, only the n⁺ type semiconductor region 12e is illustrated in FIG. 19.

Thus, by the n⁻ type semiconductor region 11a and the n⁺ type semiconductor region 12a with the impurity concentration higher than that of the n⁻ type semiconductor region 11a, the n-type semiconductor region MS which functions as a source region of the memory transistor MT is formed. Also, by the n⁻ type semiconductor region 11b and the n⁺ type semiconductor region 12b with the impurity concentration higher than that of the n⁻ type semiconductor region 11b, the n-type semiconductor region MD which functions as a drain region of the control transistor CT is formed. The semiconductor region MS is formed in the upper layer section of the p-type well PW1 of a portion positioned on the opposite side of the control gate electrode CG by sandwiching the memory gate electrode MG in plan view. The semiconductor region MD is formed in the upper layer section of the p-type well PW1 of a portion positioned on the opposite side of the memory gate electrode MG by sandwiching the control gate electrode CG in plan view.

Activation annealing is thereafter performed which is a heat treatment for activating the impurity introduced into the n⁻ type semiconductor regions 11a, 11b, 11d, and 11e, the p⁻ type semiconductor region 11c, the n⁺ type semiconductor regions 12a, 12b, 12d, and 12e, the p⁺ type semiconductor region 12c, and the like.

Thus, as shown in FIG. 19, in the memory cell region 1A, the control transistor CT and the memory transistor MT are formed, and the memory cell MC1 as a nonvolatile memory is formed by the control transistor CT and the memory transistor MT. In other words, the memory cell MC1 as a nonvolatile memory is formed by the control gate electrode CG, the gate insulation film GIt, the memory gate electrode MG, and the gate insulation film GIm.

Also, as shown in FIG. 19, the high break down voltage MISFET QH is formed in the peripheral circuit region 1B, and the low break down voltage MISFET QL is formed in the peripheral circuit region 1C. More specifically, the high break down voltage MISFET QH is formed by the gate electrode GEH and the gate insulation film GIH, and the low break down voltage MISFET QL is formed by the gate electrode GEL and the gate insulation film GIL. Also, in the peripheral circuit region 1D, the first capacitor C1 configured of the first capacitor electrode CE1A, the first capacitor insulation film CZ1A, and the second capacitor electrode CE2A and the second capacitor C2 configured of the second capacitor electrode CE2A, the second capacitor insulation film CZ2A, and the third capacitor electrode CE3A are formed, and the first capacitor C1 and the second capacitor C2 are laminatedly arranged and form the laminated type capacitor element CS.

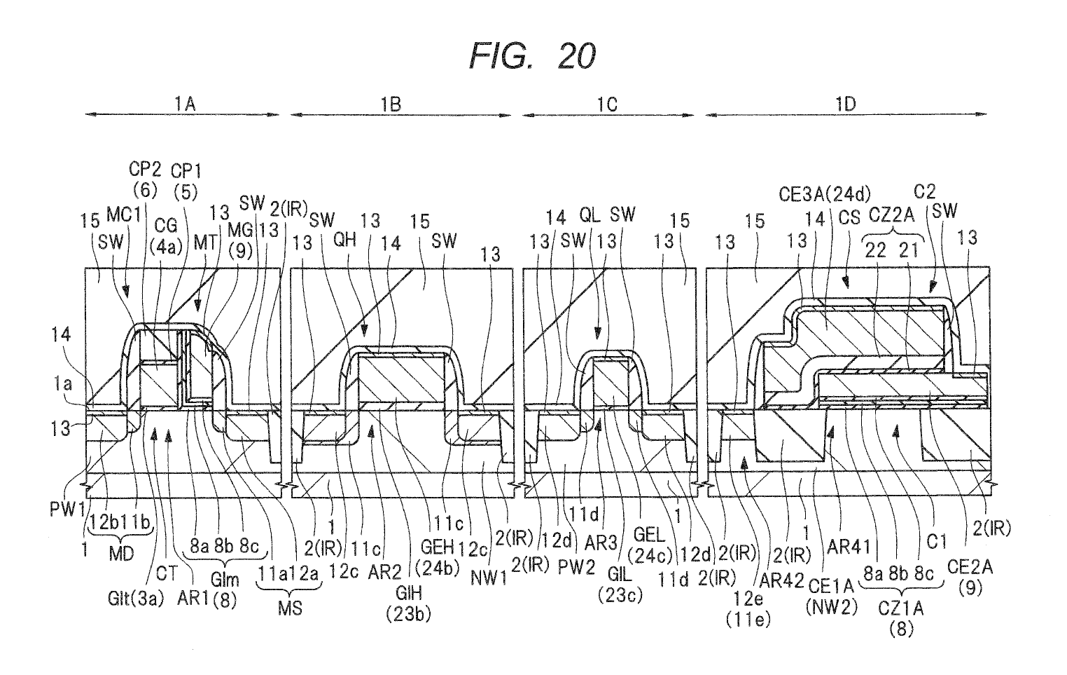

Next, as shown in FIG. 20, the metal silicide layers 13, the insulation films 14, and the inter layer insulation films 15 are formed (step S21 of FIG. 5).

In step S21, first, as shown in FIG. 20, the metal silicide layers 13 are formed. By performing known salicide process, as shown in FIG. 20, the metal silicide layers 13 can be formed over each of the n⁺ type semiconductor regions 12a, 12b, 12d, and 12e, and the p⁺ type semiconductor region 12c.

The metal silicide layers 13 are also formed over the upper surfaces of the memory gate electrode MG, the gate electrode GEH, the gate electrode GEL, the first capacitor electrode CE1A, and the second capacitor electrode CE2A. The metal silicide layer 13 can be formed of a cobalt silicide layer, a nickel silicide layer, or a platinum-added nickel silicide layer for example.

In step S21, next, the insulation films 14 are formed as shown in FIG. 20. The insulation films 14 are formed so as to cover the cap insulation film CP2, the gate insulation film GIm, the memory gate electrode MG, the gate electrodes GEH and GEL, the first capacitor electrode CE1A, the second capacitor electrode CE2A, and the side wall spacers SW. The insulation film 14 is configured of a silicon nitride film for example. The insulation film 14 can be formed by the CVD method for example.

In step S21, next, as shown in FIG. 20, the interlayer insulation films 15 are formed over the insulation films 14. The interlayer insulation film 15 is configured of a single film of a silicon oxide film, or a laminated film of a silicon nitride film and a silicon oxide film, and the like. After forming the interlayer insulation films 15 by the CVD method for example, the upper surfaces of the interlayer insulation films 15 are flattened.

Next, as shown in FIG. 2, the plugs PG, PG1, PG2, and PG3 penetrating the interlayer insulation films 15 are formed (step S22 of FIG. 5). First, the contact holes CNT are formed in the interlayer insulation films 15 by subjecting the interlayer insulation films 15 to dry etching using photolithography using a resist pattern (not illustrated) formed over the interlayer insulation films 15 as etching masks. Next, within the contact holes CNT, the conductive plugs PG, PG1, PG2, and PG3 formed of tungsten (W) and the like are formed as the conductor sections.

In order to form the plugs PG, PG1, PG2, and PG3, for example, a barrier conductor film configured of a titanium (Ti) film, a titanium nitride (TiN) film, or a laminated film thereof for example is formed over the inter-layer insulation film 15 including the inside of the contact hole CNT. Then, main conductor films configured of tungsten (W) films and the like are formed over the barrier conductor films so as to fill up the contact holes CNT, and unnecessary main conductor films and the barrier conductor films over the interlayer insulation films 15 are removed by the CMP (Chemical Mechanical Polishing) method, or the etch back method and the like. Thus, the plugs can be formed. Also, in FIG. 2, for simplification of the drawing, the barrier conductor film and the main conductor film forming the plugs PG are illustrated integratedly.

The contact holes CNT and the plugs PG embedded therein are formed over the n⁺ type semiconductor regions 12b and 12d, and over the p⁺ type semiconductor region 12c. The plug PG1 is formed over the n⁺ type semiconductor region 12e, the plug PG2 is formed over the second capacitor electrode CE2A, and the plug PG3 is formed over the third capacitor electrode CE3A.

In the manner described above, the semiconductor device of the present first embodiment described above using FIG. 2 is manufactured. Also, the wiring with the main conductor film of copper (Cu) for example can be formed over the interlayer insulation films 15 where the plugs PG are embedded using the damascene technology for example, however, the explanation thereof will be omitted here.

### <Main Feature and Effect of Present Embodiment>

In the method for manufacturing a semiconductor device according to the present first embodiment, a capacitor element can be formed utilizing the method for manufacturing a semiconductor device of working the control gate electrode of the memory cell, the laminated film including the electric charge accumulation section, and the memory gate electrode, and thereafter forming the well regions for forming the MISFET of the peripheral circuit regions.

More specifically, the second capacitor C2 is formed with the insulation film 22 that is a protection film of the memory cell being made the second capacitor insulation film CZ2A. Further, although the second capacitor C2 is configured of the second capacitor electrode CE2A, the second capacitor insulation film CZ2A, and the third capacitor electrode CE3A, the second capacitor electrode CE2A is configured of the conductor film 9 that forms the memory gate electrode MG of the memory cell MC1, and the third capacitor electrode CE3A is configured of the conductor film 24d of the same layer of the conductor film 24c that forms the gate electrode GEL of the MISFET QL.

Also, the second capacitor C2 is formed with the laminated film of the insulation film 21 configured of a silicon oxide film and the insulation film 22 configured of a silicon nitride film being made the second capacitor insulation film CZ2A. Electric charge leakage of the second capacitor insulation film CZ2A can be reduced by achieving the laminated structure of the insulation film 22 configured of a silicon nitride film liable to cause the electric charge leakage with a single layer and the insulation film 21 configured of a silicon oxide film having dense film quality.

Also, the first capacitor C1 is configured of the first capacitor electrode CE1A, the first capacitor insulation film CZ1A, and the second capacitor electrode CE2A. Also, the first capacitor electrode CE1A is configured of the n-type well NW2 formed in the same step of the n-type well NW1 of the MISFET QH, the first capacitor insulation film CZ1A is configured of an insulation film of the same layer of the insulation film 8 of the memory cell MC1, and, as described above, the second capacitor electrode CE2A is configured of the conductor film 9 that forms the memory gate electrode MG.

Further, by making the second capacitor electrode CE2A common to the first capacitor C1 and the second capacitor C2, the laminated type capacitor element CS is formed in which the first capacitor C1 and the second capacitor C2 are laminated.

### Second Embodiment

The first embodiment is the method for manufacturing a semiconductor device in which the first capacitor electrode CE1A of the laminated type capacitor element CS is configured of the second well NW2 of n-type, the first capacitor insulation film CZ1A is configured of the insulation film 8, the second capacitor electrode CE2A is configured of the conductor film 9, the second capacitor insulation film CZ2A is configured of the insulation films 21 and 22, and the third capacitor electrode CE3A is configured of the conductor film 24d. On the other hand, the present second embodiment is a method for manufacturing a semiconductor device in which a first capacitor electrode CE1B of the laminated type capacitor element CS is configured of the second well NW2 of n-type, a first capacitor insulation film CZ1B is configured of an insulation film 30d, a second capacitor electrode CE2B is configured of the conductor film 4d, a second capacitor insulation film CZ2B is configured of the insulation films 21 and 22, and a third capacitor electrode CE3B is configured of the conductor film 24d.

### <Structure of Semiconductor Device>

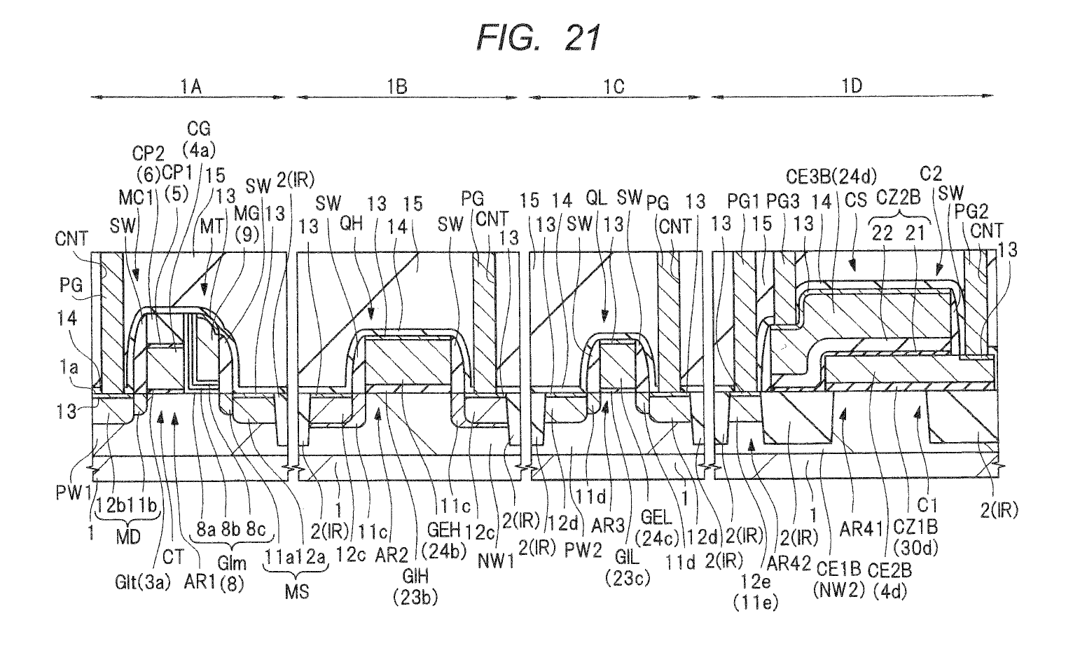

First, the structure of a semiconductor device of the present second embodiment will be explained referring to the drawings. FIG. 21 is an essential part cross-sectional view of the semiconductor device of the present second embodiment.

In the present second embodiment also, similarly to the first embodiment, the semiconductor device includes the memory cell region 1A, and the peripheral circuit regions 1B, 1C and 1D as the regions of a part of the main surface 1a of the semiconductor substrate 1. The memory cell MC1 is formed in the memory cell region 1A, the MISFET QH is formed in the peripheral circuit region 1B, the MISFET QL is formed in the peripheral circuit region 1C, and the laminated type capacitor element CS is formed in the peripheral circuit region 1D.

In the essential part cross-sectional view of the semiconductor device shown in FIG. 21, the structure of the memory cell MC1 of the memory cell region 1A and the MISFET QH and the MISFET QL of the peripheral circuit regions 1B and 1C is similar to that of the first embodiment, and therefore explanation thereof is interchangeable with that of the first embodiment.

Therefore, the configuration of the laminated type capacitor element CS formed in the peripheral circuit region 1D will be explained specifically. With respect to the laminated type capacitor element CS also, the portions common to the first embodiment are marked with same reference signs, and explanation thereof is also interchangeable with that of the first embodiment.

In the peripheral circuit region 1D, the semiconductor device includes active regions AR41, AR42, and the element separation region IR. In the lower part of the active regions AR41, AR42, and the element separation region IR, the n-type well NW2 is continuously formed. The active region AR42 is a region for supplying desired potential to the n-type well NW2, and the n⁺ type semiconductor region 12e and the n⁻ type semiconductor region 11e are arranged in the active region AR42. The n-type well NW2 forms the first capacitor electrode CE1B. The n-type well NW2 forming the first capacitor electrode CE1B is formed by a step same to that of the n-type well NW1 where the p-type MISFET QH is formed.

Over the active region AR41, the second capacitor electrode CE2B is formed through the first capacitor insulation film CZ1B. In plan view, the second capacitor electrode CE2B fully covers the active region AR41, and extends to the element separation region IR adjacent to the active region AR41. The first capacitor insulation film CZ1B is formed of a silicon oxide film 30d. The second capacitor electrode CE2B is configured of the conductor film 4d, and is formed of the conductor film 4 of the same layer of the control gate electrode CG. Also, the second capacitor electrode CE2B and the first capacitor insulation film CZ1B have a same shape in plan view.

In other words, the first capacitor C1 configured of the first capacitor electrode CE1B, the first capacitor insulation film CZ1B, and the second capacitor electrode CE2B is formed in the active region AR41.

So as to cover the upper surface and the side surface of the second capacitor electrode CE2B, the third capacitor electrode CE3B is formed through the second capacitor insulation film CZ2B. The third capacitor electrode CE3B includes a portion overlapping with the second capacitor electrode CE2B in plan view and a portion spreading out from the second capacitor electrode CE2B and extending to the element separation region IR in plan view. The third capacitor electrode CE3B is configured of the conductor film 24d. As the conductor film 24d, a conductor film formed in the same layer of the conductor film 24b included in the gate electrode GEH of the MISFET QH or of the conductor film 24c included in the gate electrode GEL of the MISFET QL can be used. Also, the second capacitor insulation film CZ2B is configured of a laminated film of the insulation film 21 and the insulation film 22 formed over the insulation film 21. The insulation film 21 is configured of a silicon oxide film, and the insulation film 22 is configured of a silicon nitride film. The laminated film of the insulation film 21 and the insulation film 22 is formed so as to cover the upper surface and the side surface of the second capacitor electrode CE2B, and extends to the element separation region IR. The third capacitor electrode CE3B and the second capacitor insulation film CZ2B have a same shape in plan view. The side wall spacer SW is formed in the side wall of the third capacitor electrode CE3B and the second capacitor insulation film CZ2B.

In other words, the second capacitor C2 configured of the second capacitor electrode CE2B, the second capacitor insulation film CZ2B, and the third capacitor electrode CE3B is formed in a region where the second capacitor electrode CE2B and the third capacitor electrode CE3B overlap. Because the third capacitor electrode CE3B also fully covers the active region AR41 in plan view, the laminated type capacitor element CS in which the first capacitor C1 and the second capacitor C2 are laminated is formed in the active region AR41.

The metal silicide layers 13 are formed over the upper surface of the second capacitor electrode CE2B exposed from the third capacitor electrode CE3B and the side wall spacer SW and the upper surface of the third capacitor electrode CE3B over the n⁺ type semiconductor region 12e.

Further, explanation on FIG. 3A and FIG. 3B of the first embodiment can also read substituting the first capacitor electrode CE1A to the first capacitor electrode CE1B, the first capacitor insulation film CZ1A to the first capacitor insulation film CZ1B, the second capacitor electrode CE2A to the second capacitor electrode CE2B, the second capacitor insulation film CZ2A to the second capacitor insulation film CZ2B, and the third capacitor electrode CE3A to the third capacitor electrode CE3B.

<Method for Manufacturing Semiconductor Device>

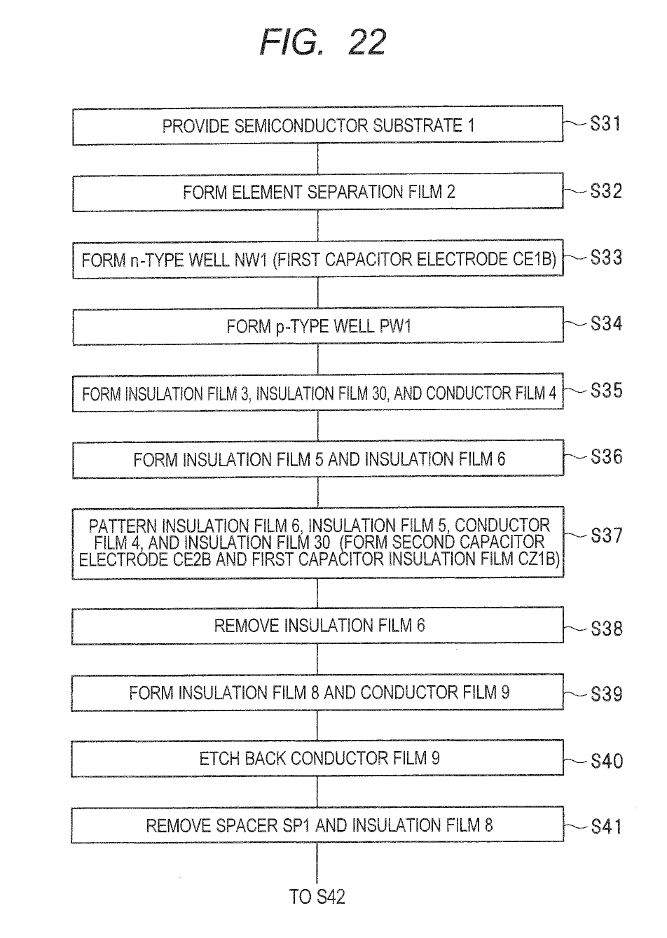

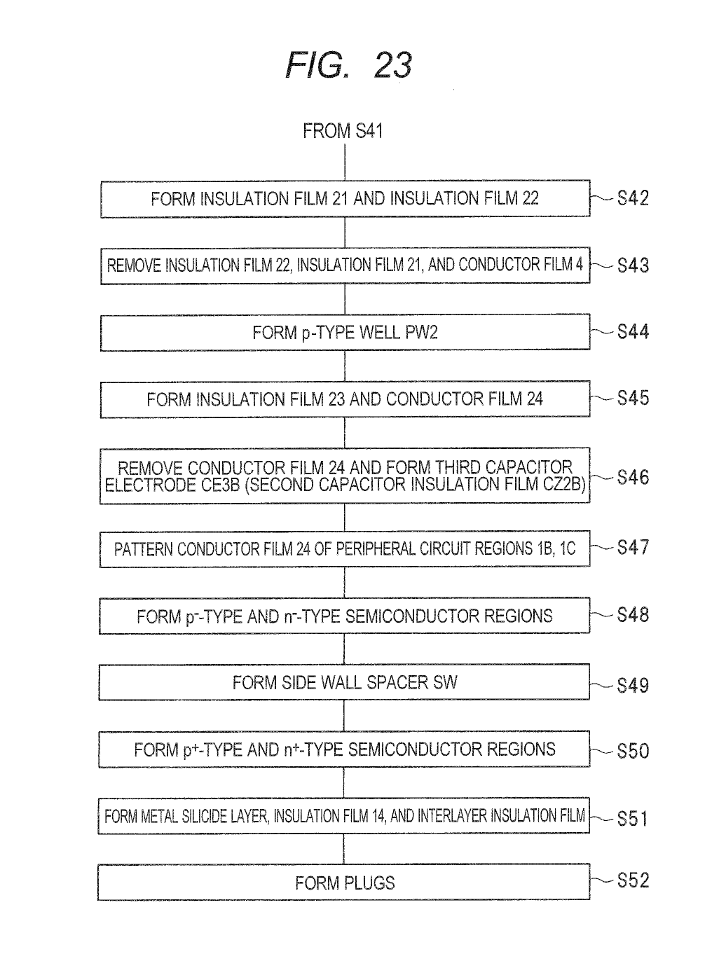

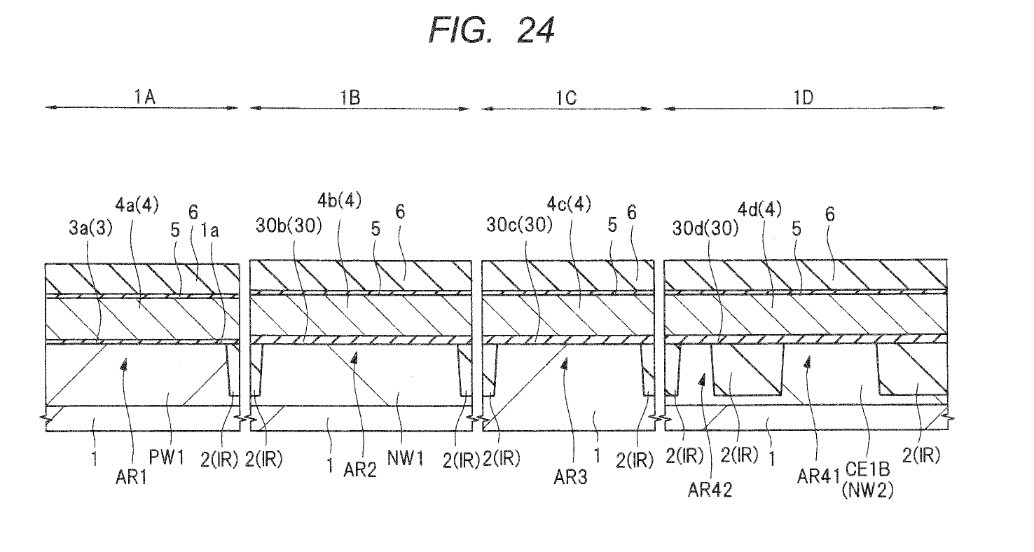

FIG. 22 and FIG. 23 are process flow charts showing a part of a manufacturing step of the semiconductor device of the second embodiment. FIG. 24-FIG. 28 are essential part cross-sectional views during a manufacturing step of the semiconductor device of the second embodiment. In the cross-sectional views of FIG. 24-FIG. 28, the essential part cross-sectional views of the memory cell region 1A and the peripheral circuit regions 1B, 1C and 1D are illustrated, and the states the memory cell MC1 is formed in the memory cell region 1A, the MISFET QH is formed in the peripheral circuit region 1B, the MISFET QL is formed in the peripheral circuit region 1C, and the laminated type capacitor element CS is formed in the peripheral circuit region 1D respectively are illustrated.

In the present second embodiment, similarly to the first embodiment, the steps similar to step S1 to step S4 of FIG. 4 (from step S31 to step S34 of FIG. 22) are performed. As a result, the n-type well NW1 is formed in the active region AR2 in the peripheral circuit region 1B, and the n-type well NW2 is formed in the active regions AR41 and AR42 and the lower part of the element separation film 2 in the peripheral circuit region 1D. Also, the p-type well PW1 is formed in the memory cell region 1A. Further, similarly to the first embodiment, the n-type well NW2 becomes the first capacitor electrode CE1B of the laminated type capacitor element CS.

Next, as shown in FIG. 24, the insulation films 3 and 30 and the conductor film 4 are formed over the entire surface of the main surface 1a of the semiconductor substrate 1 (step S35 of FIG. 22). FIG. 24 corresponds to FIG. 7 of the first embodiment.

In step S35, first, as shown in FIG. 24, similarly to the first embodiment, in the memory cell region 1A, the insulation film 3 is formed over the main surface 1a of the semiconductor substrate 1. Out of the insulation film 3, a portion formed in the memory cell region 1A is called the insulation film 3a. In the present second embodiment, the insulation films 30 are formed in the peripheral circuit regions 1B, 1C, and 1D. Out of the insulation films 30, a portion formed in the peripheral circuit region 1B is called an insulation film 30b, a portion formed in the peripheral circuit region 1C is called an insulation film 30c, and a portion formed in the peripheral circuit region 1D is called the insulation film 30d. The film thickness of the insulation film 30d is made equal to or thicker than the film thickness of the gate insulation film GIH of the MISFET QH shown in FIG. 21. The insulation film 30 is configured of a silicon oxide film, and is formed by the thermal oxidation method. As the insulation film 30, a silicon nitride film or a silicon oxynitride film may be used, and the manufacturing method such as the ALD method or the CVD method may be used.

Next, similarly to the first embodiment, the conductor film 4 is formed over the insulation film 3a of the memory cell region 1A, and over the insulation films 30b, 30c, and 30d of the peripheral circuit regions 1B, 1C, and 1D. Similarly to the first embodiment, out of the conductor film 4, a portion formed in the memory cell region 1A is called the conductor film 4a, a portion formed in the peripheral circuit region 1B is called the conductor film 4b, a portion formed in the peripheral circuit region 1C is called the conductor film 4c, and a portion formed in the peripheral circuit region 1D is called the conductor film 4d.

Next, as shown in FIG. 24, similarly to the first embodiment, the insulation film 5 and the insulation film 6 are formed over the entire surface of the main surface 1a of the semiconductor substrate 1 or over the conductor film 4 (step S36 of FIG. 22).

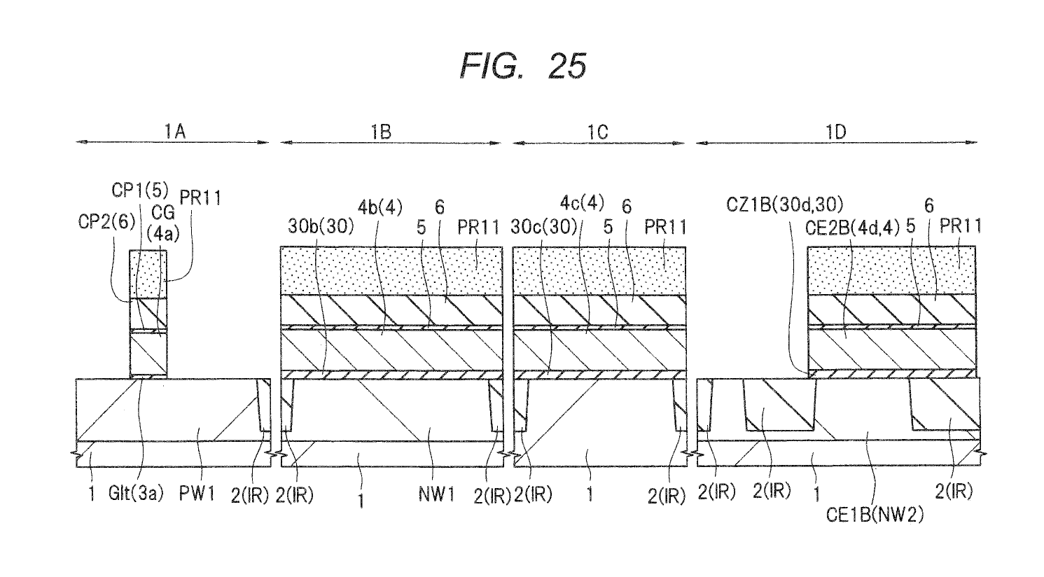

Next, as shown in FIG. 25, similarly to the first embodiment, the insulation film 6, the insulation film 5, and the conductor film 4 are patterned (step S37 of FIG. 22). FIG. 25 corresponds to FIG. 8 of the first embodiment.

First, a resist film PR11 is formed over the insulation film 6. The resist film PR11 has a pattern similar to that of the first embodiment in the memory cell region 1A and the peripheral circuit regions 1B and 1C, but has a pattern of covering a region for forming the second capacity electrode CE2B and exposing the other portions in the peripheral circuit region 1D. Next, using the resist film PR11 as a mask, the insulation film 6, the insulation film 5, the conductor film 4, and the insulation films 3a and 30d are etched and patterned by dry etching and the like for example. Thus, similarly to the first embodiment, in the memory cell region 1A, the cap insulation film CP2, the cap insulation film CP1, the control gate electrode CG, and the gate insulation film GIt are formed. Also, in the peripheral circuit region 1D, the second capacitor electrode CE2B configured of the conductor film 4d and the first capacitor insulation film CZ1B configured of the insulation film 30d are formed.

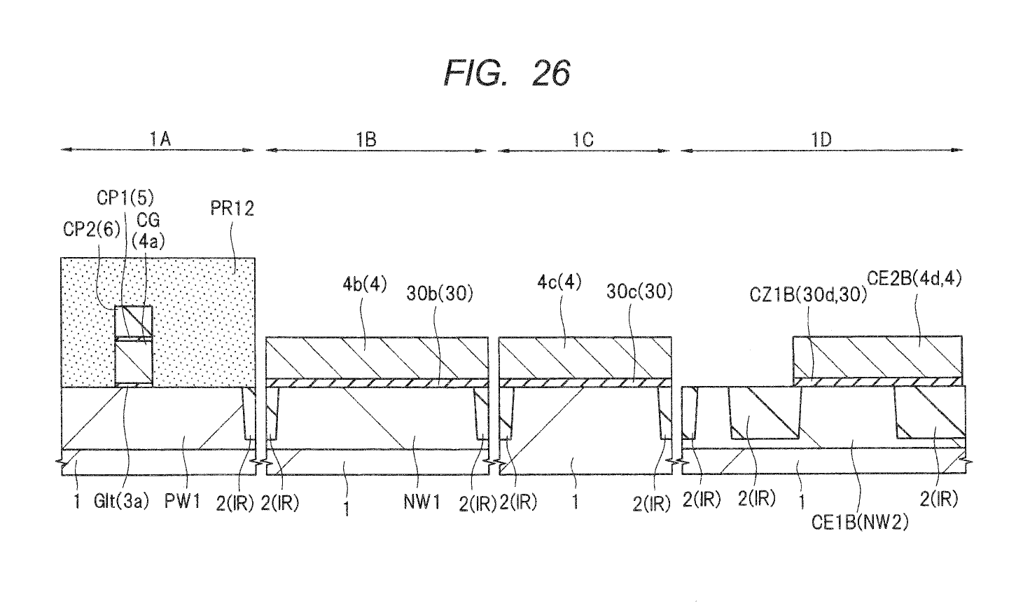

Next, as shown in FIG. 26, in the peripheral circuit regions 1B, 1C, and 1D, the insulation films 6 are removed (step S38 of FIG. 22). FIG. 26 corresponds to FIG. 9 of the first embodiment. The method for removing the insulation films 6 is similar to that of the first embodiment, and a resist film PR12 corresponds to the resist film PR2 of the first embodiment. The resist film PR12 of the present second embodiment has a pattern similar to that of the resist film PR2 in the memory cell region 1A and the peripheral circuit regions 1B and 1C, but exposing the peripheral circuit region 1D. Therefore, when dry etching is performed using the resist film PR12 as an etching mask, in the peripheral circuit region 1D, the insulation film 6 and the insulation film 5 over the second capacitor electrode CE2B are also removed.

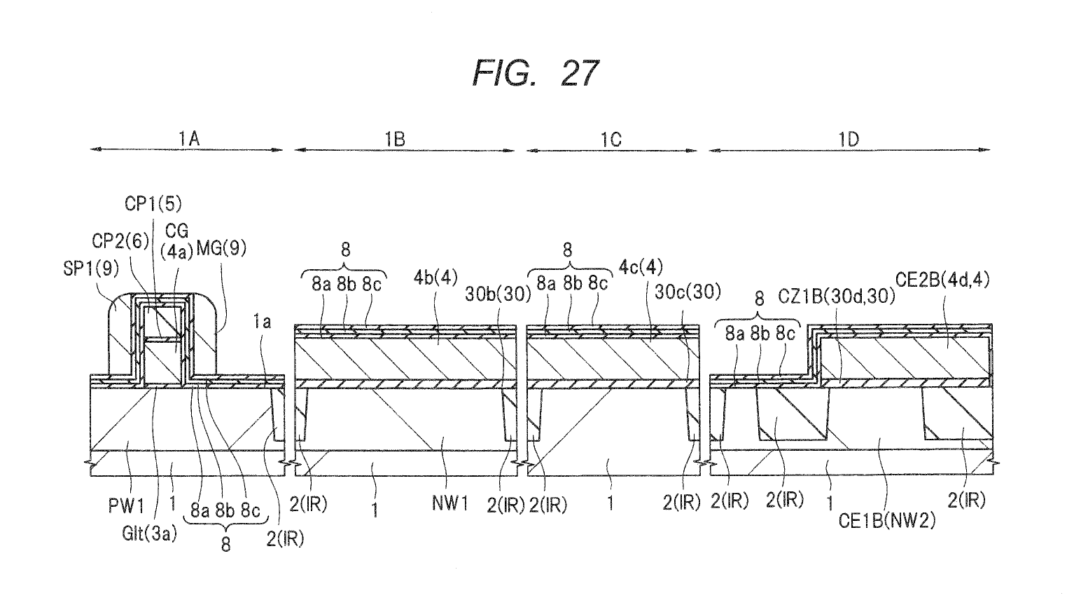

Next, after removing the resist film PR12, as shown in FIG. 27, the insulation film 8 and the conductor film 9 are formed (step S39 of FIG. 22), and the conductor film 9 is thereafter subjected to etching back (step S40 of FIG. 22). FIG. 27 corresponds to FIG. 10 and FIG. 11 of the first embodiment.

First, as explained in step S9 of the first embodiment, the insulation film 8 and the conductor film 9 are formed over the main surface 1a of the semiconductor substrate 1. Next, the conductor film 9 is subjected to anisotropic dry etching. Although the resist film PR3 was arranged in the peripheral circuit region 1D in the first embodiment, a resist film is not formed in the present second embodiment. By the anisotropic dry etching, the conductor film 9 is left in a side wall spacer shape through the insulation film 8 over the side wall or over the side surface of both sides of the control gate electrode CG in the memory cell region 1A, and the conductor films 9 of the peripheral circuit regions 1B, 1C, and 1D are removed.

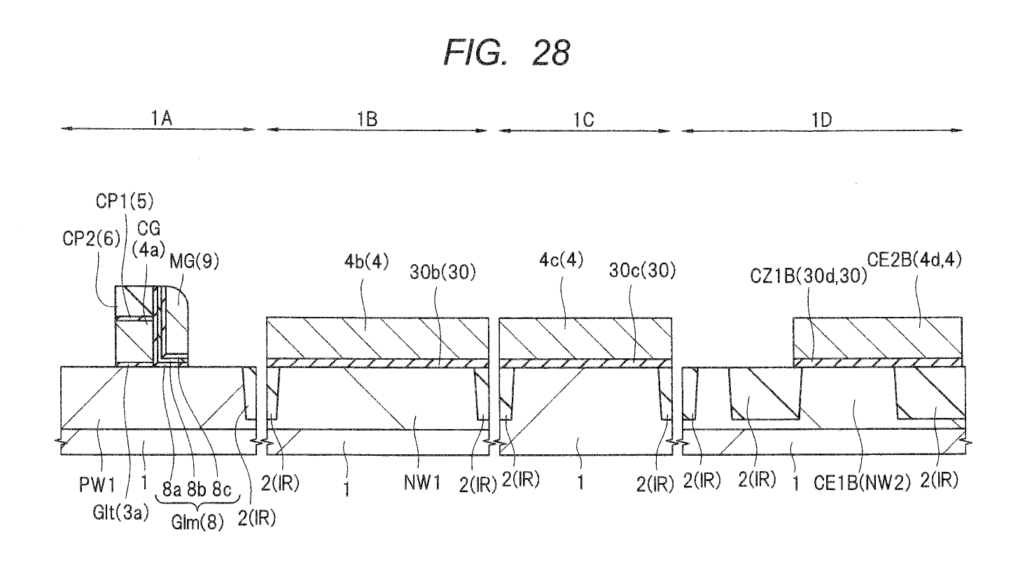

Next, as shown in FIG. 28, the spacer SP1 and the insulation film 8 are removed (step S41 of FIG. 22). FIG. 28 corresponds to FIG. 12 of the first embodiment. After removing the spacer SP1 of the memory cell region 1A, the insulation film 8 of a portion not covered by the memory gate electrode MG is removed by etching such as wet etching for example. At this time, the insulation films 8 of the peripheral circuit regions 1B, 1C, and 1D are also removed.

Thereafter, by performing step S42 to step S52 of FIG. 23 (corresponding to step S12 to step S22 of FIG. 5) similarly to the first embodiment, the semiconductor device of the present second embodiment shown in FIG. 21 is completed.

<Main Feature and Effect of Present Embodiment>

In the method for manufacturing a semiconductor device according to the present second embodiment, a capacitor element can be formed utilizing the method for manufacturing a semiconductor device of working the control gate electrode of the memory cell, the laminated film including the electric charge accumulation section, and the memory gate electrode, and thereafter forming the well regions for forming the MISFET of the peripheral circuit regions.

More specifically, the second capacitor C2 is formed with the insulation film 22 that is a protection film of the memory cell being made the second capacitor insulation film CZ2B. Further, although the second capacitor C2 is configured of the second capacitor electrode CE2B, the second capacitor insulation film CZ2B, and the third capacitor electrode CE3B, the second capacitor electrode CE2B is configured of the conductor film 4d of the same layer of the conductor film 4a that forms the control gate electrode CG of the memory cell MC1, and the third capacitor electrode CE3B is configured of the conductor film 24d of the same layer of the conductor film 24c that forms the gate electrode GEL of the MISFET QL.

Also, the second capacitor C2 is formed with the laminated film of the insulation film 21 configured of a silicon oxide film and the insulation film 22 configured of a silicon nitride film being made the second capacitor insulation film CZ2B. Electric charge leakage of the second capacitor insulation film CZ2B can be reduced by achieving the laminated structure of the insulation film 22 configured of a silicon nitride film liable to cause the electric charge leakage with a single layer and the insulation film 21 configured of a silicon oxide film having dense film quality.

Further, by making the second capacitor electrode CE2B common to the first capacitor C1 and the second capacitor C2, the laminated type capacitor element CS is formed in which the first capacitor C1 and the second capacitor C2 are laminated.

In the first embodiment, as shown in FIG. 11, in step S10, a photomask (reticle) for forming the resist film PR3 for patterning the second capacitor electrode CE2A of the peripheral circuit region 1D is required. In the present second embodiment, because the pattern of the resist film PR11 is formed using the photomask for forming the control gate electrode CG as shown in FIG. 25, the number of sheets of the mask in the manufacturing step of the semiconductor device can be reduced, and the manufacturing cost can be lowered.

### Third Embodiment

The present third embodiment is a method for manufacturing a semiconductor device in which a first capacitor electrode CE1C of the laminated type capacitor element CS is configured of the second well NW2 of n-type, a first capacitor insulation film CZ1C is configured of an insulation film 30d, a second capacitor electrode CE2C is configured of the conductor film 4d, a second capacitor insulation film CZ2C is configured of the insulation film 8, and a third capacitor electrode CE3C is configured of the conductor film 9.

### <Structure of Semiconductor Device>

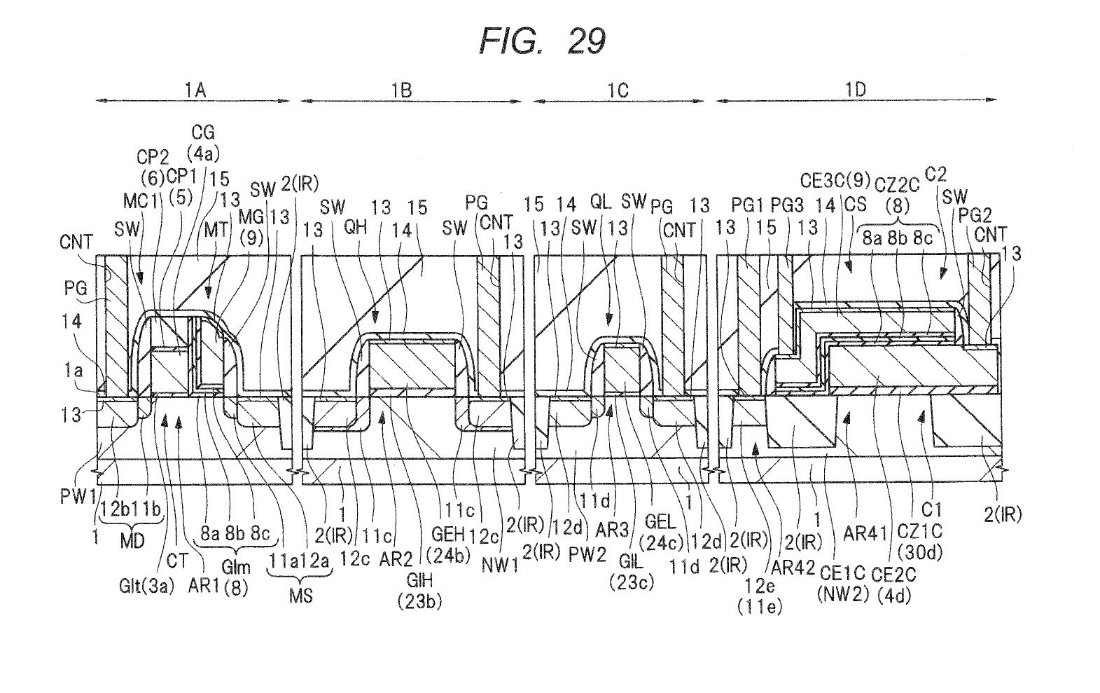

First, the structure of a semiconductor device of the present third embodiment will be explained referring to the drawings. FIG. 29 is an essential part cross-sectional view of the semiconductor device of the present third embodiment.

In the present third embodiment also, similarly to the first or second embodiment, the semiconductor device includes the memory cell region 1A, and the peripheral circuit regions 1B, 1C and 1D as the regions of a part of the main surface 1a of the semiconductor substrate 1. The memory cell MC1 is formed in the memory cell region 1A, the MISFET QH is formed in the peripheral circuit region 1B, the MISFET QL is formed in the peripheral circuit region 1C, and the laminated type capacitor element CS is formed in the peripheral circuit region 1D.

In the essential part cross-sectional view of the semiconductor device shown in FIG. 29, the structure of the memory cell MC1 of the memory cell region 1A and the MISFET QH and the MISFET QL of the peripheral circuit regions 1B and 1C is similar to that of the first or second embodiment, and therefore explanation thereof is interchangeable with that of the first embodiment.

Therefore, the configuration of the laminated type capacitor element CS formed in the peripheral circuit region 1D will be explained specifically. With respect to the laminated type capacitor element CS also, the portions common to the first or second embodiment are marked with same reference signs, and explanation thereof is also interchangeable with that of the first or second embodiment.

In the peripheral circuit region 1D, the semiconductor device includes active regions AR41, AR42, and the element separation region IR. In the lower part of the active regions AR41, AR42, and the element separation region IR, the n-type well NW2 is continuously formed. The active region AR42 is a region for supplying desired potential to the n-type well NW2, and the n⁺ type semiconductor region 12e and the n⁻ type semiconductor region 11e are arranged in the active region AR42. The n-type well NW2 forms the first capacitor electrode CE1C. The n-type well NW2 forming the first capacitor electrode CE1C is formed by a step same to that of the n-type well NW1 where the p-type MISFET QH is formed.

Over the active region AR41, the second capacitor electrode CE2C is formed through the first capacitor insulation film CZ1C. In plan view, the second capacitor electrode CE2C fully covers the active region AR41, and extends to the element separation region IR adjacent to the active region AR41. The first capacitor insulation film CZ1C is formed of a silicon oxide film 30d. The second capacitor electrode CE2C is configured of the conductor film 4d, and is formed of the conductor film 4 of the same layer of the control gate electrode CG. Also, the second capacitor electrode CE2C and the first capacitor insulation film CZ1C have a same shape in plan view.

In other words, the first capacitor C1 configured of the first capacitor electrode CE1C, the first capacitor insulation film CZ1C, and the second capacitor electrode CE2C is formed in the active region AR41.

So as to cover the upper surface and the side surface of the second capacitor electrode CE2C, the third capacitor electrode CE3C is formed through the second capacitor insulation film CZ2C. The third capacitor electrode CE3C includes a portion overlapping with the second capacitor electrode CE2C in plan view and a portion spreading out from the second capacitor electrode CE2C and extending to the element separation region IR in plan view. The third capacitor electrode CE3C is configured of the conductor film 9. As the conductor film 9, a conductor film formed in the same layer of the conductor film 9 included in the memory gate electrode MG can be used. Also, the second capacitor insulation film CZ2C is configured of the insulation film 8. The insulation film 8 is configured of a laminated film of the silicon oxide film 8a, the silicon nitride film 8b, and the silicon oxide film 8c. The insulation film 8 is formed so as to cover the upper surface and the side surface of the second capacitor electrode CE2C, and extends to the element separation region IR. The third capacitor electrode CE3C and the second capacitor insulation film CZ2C have a same shape in plan view. The side wall spacer SW is formed in the side wall of the third capacitor electrode CE3C and the second capacitor insulation film CZ2C.

In other words, the second capacitor C2 configured of the second capacitor electrode CE2C, the second capacitor insulation film CZ2C, and the third capacitor electrode CE3C is formed in a region where the second capacitor electrode CE2C and the third capacitor electrode CE3C overlap. Because the third capacitor electrode CE3C also fully covers the active region AR41 in plan view, the laminated type capacitor element CS in which the first capacitor C1 and the second capacitor C2 are laminated is formed in the active region AR41.

The metal silicide layers 13 are formed over the upper surface of the second capacitor electrode CE2C exposed from the third capacitor electrode CE3C and the side wall spacer SW and the upper surface of the third capacitor electrode CE3C over the n⁺ type semiconductor region 12e.

Further, explanation on FIG. 3A and FIG. 3B of the first embodiment can also read substituting the first capacitor electrode CE1A to the first capacitor electrode CE1C, the first capacitor insulation film CZ1A to the first capacitor insulation film CZ1C, the second capacitor electrode CE2A to the second capacitor electrode CE2C, the second capacitor insulation film CZ2A to the second capacitor insulation film CZ2C, and the third capacitor electrode CE3A to the third capacitor electrode CE3C.

<Method for Manufacturing Semiconductor Device>

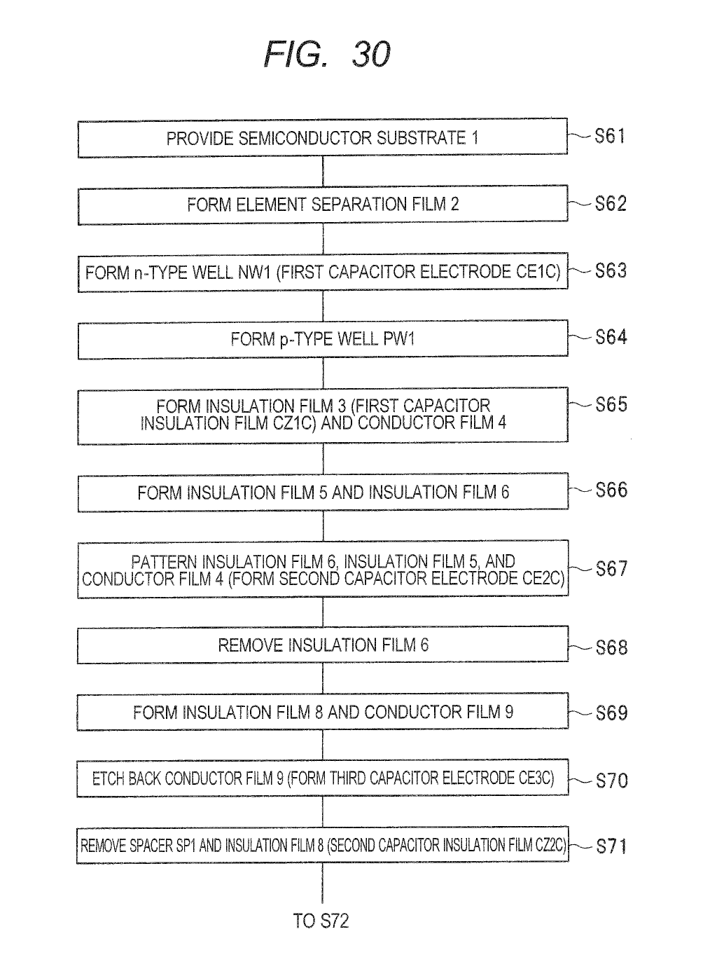

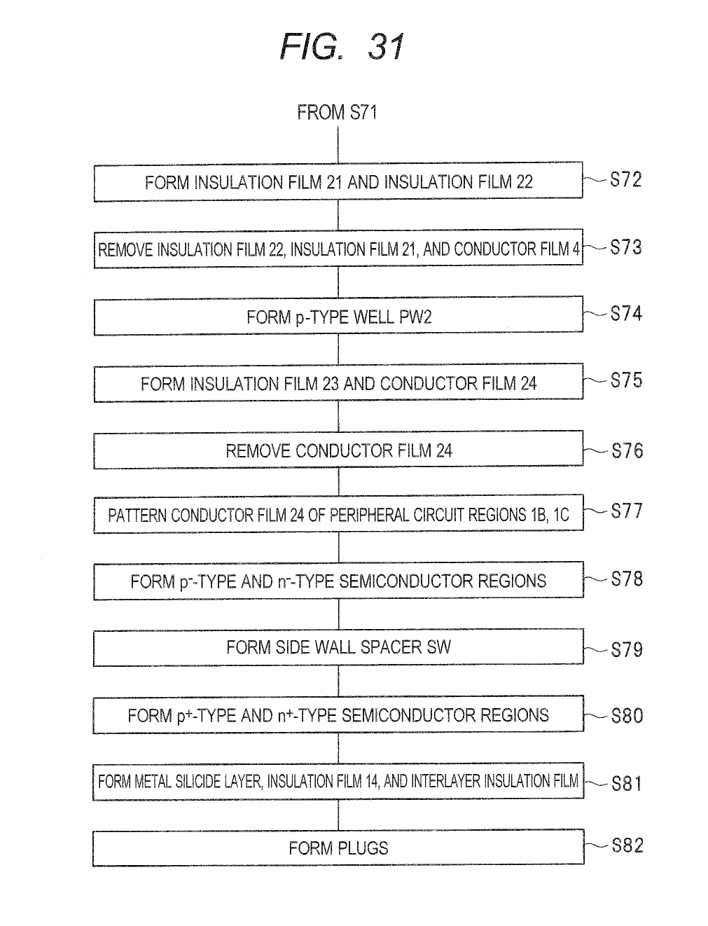

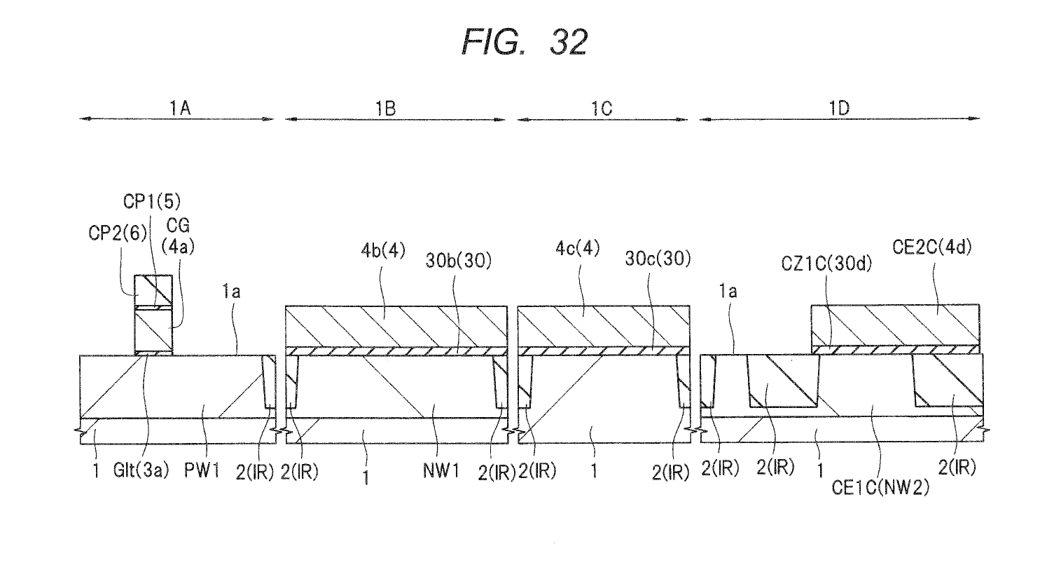

FIG. 30 and FIG. 31 are process flow charts showing a part of a manufacturing step of the semiconductor device of the third embodiment. FIG. 32-FIG. 35 are essential part cross-sectional views during a manufacturing step of the semiconductor device of the third embodiment. In the cross-sectional views of FIG. 32-FIG. 35, the essential part cross-sectional views of the memory cell region 1A and the peripheral circuit regions 1B, 1C and 1D are illustrated, and the states the memory cell MC1 is formed in the memory cell region 1A, the MISFET QH is formed in the peripheral circuit region 1B, the MISFET QL is formed in the peripheral circuit region 1C, and the laminated type capacitor element CS is formed in the peripheral circuit region 1D respectively are illustrated.

In the present third embodiment, similarly to the second embodiment, the steps similar to step S31 to step S38 of FIG. 22 (from step S61 to step S68 of FIG. 30) are performed. A state the resist film PR12 is removed after performing step S38 of the second embodiment which is a state step S68 of the present third embodiment is completed is shown in FIG. 32.

As shown in FIG. 32, in the memory cell region 1A, the gate insulation film GIt, the control gate electrode CG, and the cap insulation films CP1 and CP2 are formed over the main surface 1a of the semiconductor substrate 1. In the peripheral circuit region 1D, the first capacitor electrode CE1C configured of the n-type well NW2 is formed over the semiconductor substrate 1, the first capacitor insulation film CZ1C configured of the insulation film 30d is formed over the main surface 1a of the semiconductor substrate 1, and the second capacitor electrode CE2C is formed over the first capacitor insulation film CZ1C.

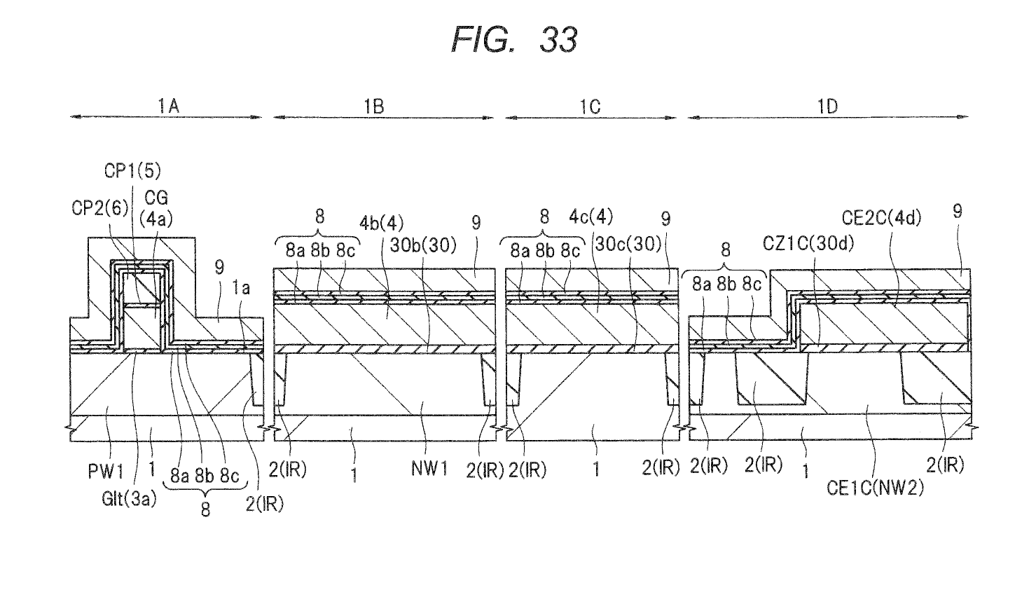

Next, as shown in FIG. 33, the insulation film 8 and the conductor film 9 are formed (step S69 of FIG. 30). FIG. 33 corresponds to FIG. 10 of the first embodiment. As shown in FIG. 33, in the peripheral circuit region 1D, the insulation film 8 and the conductor film 9 are formed along the upper surface and the side surface of the second capacitor electrode CE2C. As explained in the first embodiment, the insulation film 8 is a laminated film of the silicon oxide film 8a, the silicon nitride film 8b, and the silicon oxide film 8c.

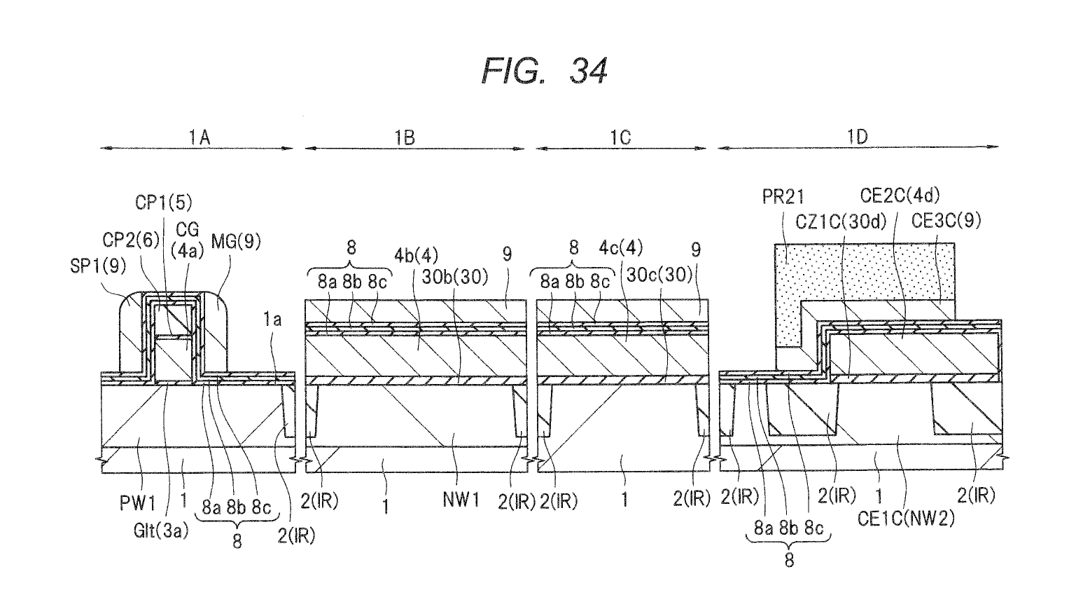

Next, as shown in FIG. 34, the conductor film 9 is etched back by the anisotropic dry etching technology, and the memory gate electrode MG and the third capacitor electrode CE3C are formed (step S70 of FIG. 30). FIG. 34 corresponds to FIG. 11 of the first embodiment. As shown in FIG. 34, a resist film PR21 having a pattern of covering a portion for forming the third capacitor electrode CE3C in the peripheral circuit region 1D and exposing the other regions is formed. The resist film PR21 has a pattern of exposing the memory cell region 1A and the peripheral circuit regions 1B and 1C. By subjecting the conductor film 9 to anisotropic dry etching using this resist film PR21 as a mask, the memory gate electrode MG is formed in the memory cell region 1A, and the third capacitor electrode CE3C is formed in the peripheral circuit region 1D.

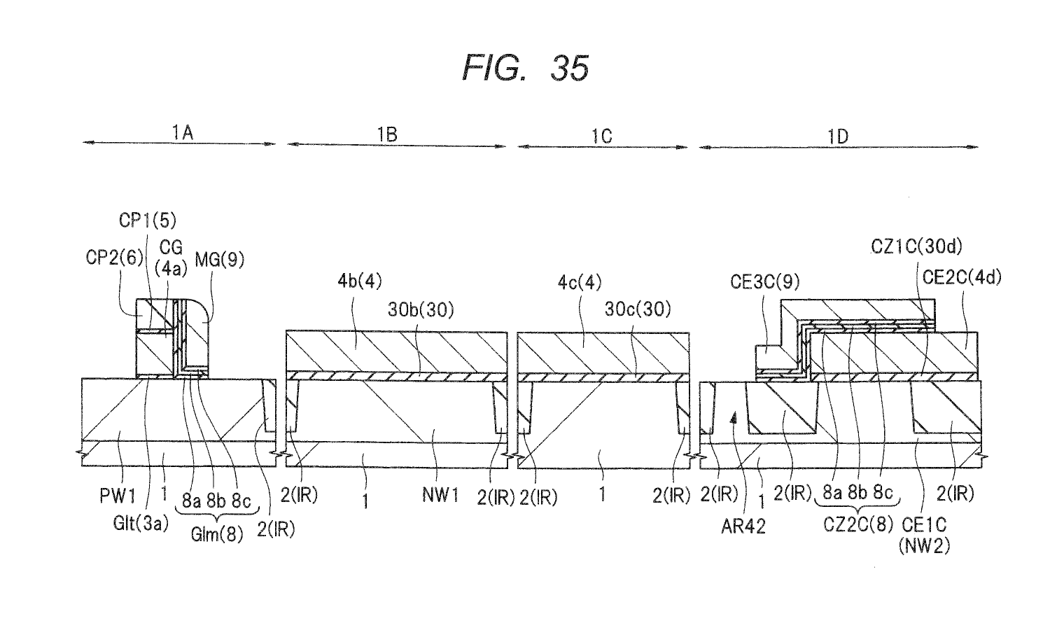

Next, as shown in FIG. 35, the insulation film 8 is removed (step S71 of FIG. 30). FIG. 35 corresponds to FIG. 12 of the first embodiment.

In step S71, similarly to the first embodiment, in the memory cell region 1A, the gate insulation film GIm configured of the insulation film 8 is formed between the memory gate electrode MG and the p-type well PW1 and between the memory gate electrode MG and the control gate electrode CG. In the peripheral circuit region 1D, the insulation film exposed from the third capacitor electrode CE3C is removed by etching, and the active region AR42 and a part of the upper surface of the second capacitor electrode CE2C are exposed. Below the third capacitor electrode CE3C, the second capacitor insulation film CZ2C is formed.

Thereafter, by performing step S72-step S82 of FIG. 31 similarly to the first embodiment, the semiconductor device of the present third embodiment shown in FIG. 29 is completed.

Although the invention achieved by the present inventors has been explained above specifically based on the embodiments, it is needless to mention that the present invention is not limited to the embodiments and various alterations are possible within a scope not deviating from the purposes thereof.

What is claimed is:

1. A method for manufacturing a semiconductor device,
the semiconductor device comprising: a memory cell formed in a first region of a main surface of the semiconductor substrate, a first MISFET formed in a second region of the main surface; and a capacitor element formed in a third region of the main surface,
the memory cell comprising: a control gate electrode formed over the main surface of the semiconductor substrate through a first gate insulation film; and a memory gate electrode formed over the main surface of the semiconductor substrate through a second gate insulation film,
the second gate insulation film comprising an electric charge accumulation section and is interposed also between the control gate electrode and the memory gate electrode,
the first MISFET comprising: a first well region; and a first gate electrode arranged over the first well region,
the capacitor element comprising: a first capacitor electrode formed over the main surface of the semiconductor substrate; a second capacitor electrode overlapping with the first capacitor electrode in plan view and formed over the first capacitor electrode; and a first capacitor insulation film interposed between the first capacitor electrode and the second capacitor electrode,
the method comprising the steps of:
(a) providing the semiconductor substrate that comprises the first region, the second region, and the third region;
(b) forming the control gate electrode in the main surface of the semiconductor substrate through the first gate insulation film and forming the memory gate electrode in the main surface of the semiconductor substrate through the second gate insulation film in the first region;
(c) forming the first capacitor electrode over the main surface of the semiconductor substrate in the third region;
(d) forming the first insulation film so as to cover the control gate electrode and the memory gate electrode in the first region and so as to cover the first capacitor electrode in the third region;
(e) forming the first well region in the semiconductor substrate in the second region in a state the first region is covered by the first insulation film; and
(f) forming the first gate electrode over the first well region in the second region, and forming the second capacitor electrode over the first insulation film in the third region,
wherein, the first insulation film forms the first capacitor insulation film in the third region, and
wherein the first gate electrode and the second capacitor electrode are configured of a first conductor film of a same layer.

2. The method for manufacturing a semiconductor device according to claim 1,
wherein the first insulation film comprises a first silicon nitride film.

3. The method for manufacturing a semiconductor device according to claim 2,
wherein the first insulation film is configured of a laminated film of the first silicon nitride film and a first silicon oxide film arranged below the first silicon nitride film.

4. The method for manufacturing a semiconductor device according to claim 1,
wherein the second gate insulation film comprises a second silicon oxide film, a second silicon nitride film over the second silicon oxide film, and a third silicon oxide film over the second silicon nitride film.

5. The method for manufacturing a semiconductor device according to claim 4,
wherein the first capacitor electrode and the memory gate electrode are configured of a second conductor film of a same layer.

6. The method for manufacturing a semiconductor device according to claim 5, further comprising a step of:
(g) forming a second insulation film over the main surface of the semiconductor substrate in the third region,
wherein the second insulation film overlaps with the first capacitor electrode in plan view, and
wherein the second insulation film is formed in a step same to that for the second gate insulation film.

7. The method for manufacturing a semiconductor device according to claim 6, further comprising a step of:
(h) forming a second well region in the semiconductor substrate in the third region,
wherein the second well region overlaps with the first capacitor electrode and the second insulation film in plan view.

8. The method for manufacturing a semiconductor device according to claim 4,
wherein the first capacitor electrode and the control gate electrode are configured of a third conductor film of a same layer.

9. The method for manufacturing a semiconductor device according to claim 8, further comprising a step of:
(i) a second MISFET forming step for forming a third well region within the semiconductor substrate, a third gate insulation film over the third well region, and a second gate electrode over the third gate insulation film in a fourth region of the main surface of the semiconductor substrate,
wherein the second gate electrode is configured of the first conductor film.

10. The method for manufacturing a semiconductor device according to claim 9, further comprising a step of:
(j) forming a third insulation film in the main surface of the semiconductor substrate in the third region,
wherein the film thickness of the third insulation film is equal to or thicker than the film thickness of the third gate insulation film.

11. The method for manufacturing a semiconductor device according to claim 9, further comprising a step of:
(k) forming a fourth well region in the semiconductor substrate in the third region,
wherein the fourth well region is formed in a step same to that for the third well region.

12. The method for manufacturing a semiconductor device according to claim 1, further comprising a step of:
(l) removing the first insulation film in the second region between the steps (d) and (e).

13. A method for manufacturing a semiconductor device, comprising the steps of:
(a) providing a semiconductor substrate that comprises a first region that is a memory cell region, a second region that is a MISFET forming region, and a third region that is a laminated type capacitor element forming region in a main surface of the semiconductor substrate;
(b) forming a first well region in the semiconductor substrate in the third region;
(c) forming a first conductor film over the main surface of the semiconductor substrate, and forming a control gate electrode in the first region by patterning the first conductor film;
(d) forming first insulation films over the main surface of the semiconductor substrate and over a side wall of the control gate electrode in the first region, and over the main surface of the semiconductor substrate in the third region;
(e) forming a second conductor film over the first insulation film, thereafter subjecting the second conductor film to anisotropic dry etching, thereby forming a memory gate electrode in the main surface of the semiconductor substrate and the side wall of the control gate electrode through the first insulation film in the first region, and forming a first conductor piece over the first insulation film in the third region;
(f) forming second insulation films so as to cover the control gate electrode, the first insulation film, and the memory gate electrode in the first region, and so as to cover the first conductor piece in the third region;
(g) forming a second well region in the semiconductor substrate in the second region in a state the control gate electrode, the first insulation film, and the memory gate electrode are covered by the second insulation film; and
(h) forming third conductor films over the second well region of the second region and over the second insulation film of the third region, thereafter patterning the third conductor films, thereby forming a gate electrode over the second well region in the second region, and forming a second conductor piece over the second insulation film in the third region,
wherein the first well region, the first conductor piece, and the second conductor piece include portions overlapping with each other in plan view in the third region, and
wherein the laminated type capacitor element is configured of the first well region, the first insulation film, the first conductor piece, the second insulation film, and the second conductor piece.

14. The method for manufacturing a semiconductor device according to claim 13,
wherein the first insulation film comprises a first silicon oxide film, a first silicon nitride film over the first silicon oxide film, and a second silicon oxide film over the first silicon nitride film.

15. The method for manufacturing a semiconductor device according to claim 14,
wherein the second insulation film comprises a second silicon nitride film.

16. The method for manufacturing a semiconductor device according to claim 13,
wherein the first conductor film of the third region is removed in the step (c).

17. The method for manufacturing a semiconductor device, comprising the steps of:
(a) providing a semiconductor substrate that comprises a first region that is a memory cell region, a second region that is a MISFET forming region, and a third region that is a laminated type capacitor element forming region in a main surface of the semiconductor substrate;
(b) forming a first well region in the semiconductor substrate in the third region;
(c) forming a first insulation film over the first well region and in the main surface of the semiconductor substrate in the third region;
(d) forming a first conductor film over the main surface of the semiconductor substrate, and forming a control gate electrode in the first region and forming a first conductor piece over the first insulation film of the third region by patterning the first conductor film;
(e) forming second insulation films over the main surface of the semiconductor substrate and over a side wall of the control gate electrode in the first region;
(f) forming a second conductor film over the second insulation film, thereafter subjecting the second conductor film to anisotropic dry etching, and thereby forming a memory gate electrode in the main surface of the semiconductor substrate and the side wall of the control gate electrode through the second insulation film in the first region;
(g) forming third insulation films so as to cover the control gate electrode, the first insulation film, and the memory gate electrode in the first region, and so as to cover the first conductor piece in the third region;
(h) forming a second well region in the semiconductor substrate in the second region in a state the control gate electrode, the first insulation film, and the memory gate electrode are covered by the second insulation film; and
(i) forming third conductor films over the second well region of the second region and over the second insulation film of the third region, thereafter patterning the third conductor films, thereby forming a gate electrode over the second well region in the second region, and forming a second conductor piece over the second insulation film in the third region,
wherein the first well region, the first conductor piece, and the second conductor piece include portions overlapping with each other in plan view in the third region, and
wherein the laminated type capacitor element is configured of the first well region, the first insulation film, the first conductor piece, the second insulation film, and the second conductor piece.

18. The method for manufacturing a semiconductor device according to claim 17,
wherein the second insulation film comprises a first silicon oxide film, a first silicon nitride film over the first silicon oxide film, and a second silicon oxide film over the first silicon nitride film.

19. The method for manufacturing a semiconductor device according to claim 17,
wherein the third insulation film comprises a second silicon nitride film.

20. The method for manufacturing a semiconductor device according to claim 17,
wherein the second conductor film of the third region is removed in the step (f).
